(19) United States
(12) Patent Application Publication
(10) Pub. No.: US 2023/0170445 A1
(43) Pub. Date: Jun. 1, 2023

(54) LIGHT-EMITTING DIODE CHIPS AND MANUFACTURING PROCESSES THEREOF

(71) Applicant: CreeLED, Inc., Durham, NC (US)

(72) Inventors: David Suich, Durham, NC (US); Christopher P. Hussell, Raleigh, NC (US); Michael Check, Holly Springs, NC (US); Colin Blakely, Raleigh, NC (US); Steven Wuester, Wake Forest, NC (US); Brian T. Collins, Holly Springs, NC (US)

(21) Appl. No.: 17/539,685

(22) Filed: Dec. 1, 2021

Related U.S. Application Data
(63) Continuation of application No. 17/539,628, filed on Dec. 1, 2021.

(51) Int. Cl. H01L 33/48; H01L 33/00; H01L 33/50; H01L 33/58; H01L 33/60

(52) U.S. Cl. CPC H01L 33/483; H01L 33/0095; H01L 33/50; H01L 33/58; H01L 33/60; H01L 2933/0041; H01L 2933/0058

(57) ABSTRACT

Aspects disclosed herein relate to light-emitting diode (LED) chips and manufacturing processes thereof. In certain aspects, an LED chip includes an epitaxial layer with a first side and a second side, a first type contact proximate a second side of the epitaxial layer, and a wavelength conversion element including at least one lumiphore. In certain embodiments, in a flip-chip construction, a distance between the at least one lumiphore and the epitaxial layer is less than 5 microns and/or the first side of the epitaxial layer includes texturing. In certain embodiments, in a vertical stack construction, a transparent bonding layer between the epitaxial layer and the wavelength conversion element includes inorganic material. In certain embodiments, a ceramic layer is bonded to the second side of the epitaxial layer and positioned horizontally adjacent to the first type contact. Such configurations facilitate construction, decrease size, and/or increase performance of the LED chips.

### CROSS-REFERENCE TO RELATED APPLICATIONS

This application is a continuation of U.S. patent application Ser. No. 17/539,628 filed on Dec. 1, 2021, the disclosure of which is incorporated herein by reference in its entirety.

### FIELD OF THE DISCLOSURE

The present disclosure related to light-emitting diodes (LEDs), and more particularly to LED chips and manufacturing processes thereof.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An active region may be fabricated, for example, from silicon carbide, gallium nitride, gallium phosphide, aluminum nitride, and/or gallium arsenide-based materials and/or from organic semiconductor materials. Photons generated by the active region are initiated in all directions.

As advancements in modern LED technology progress, the art continues to seek improved LEDs and solid-state lighting devices having desirable illumination characteristics capable of overcoming challenges associated with conventional lighting devices.

### SUMMARY

Aspects disclosed herein relate to light-emitting diode (LED) chips and manufacturing processes thereof. In certain aspects, an LED chip includes an epitaxial layer with a first side and a second side, a first type contact proximate a second side of the epitaxial layer, and a wavelength conversion element including at least one lumiphore. In certain embodiments, in a flip-chip construction, a distance between the at least one lumiphore and the epitaxial layer is less than 5 microns and/or the first side of the epitaxial layer includes texturing. In certain embodiments, in a vertical stack construction, a transparent bonding layer between the epitaxial layer and the wavelength conversion element includes inorganic material. In certain embodiments, a ceramic layer is bonded to the second side of the epitaxial layer and positioned horizontally adjacent to the first type contact. Such configurations facilitate construction, decrease size, and/or increase performance of the LED chips.

In one aspect, an LED chip comprises an epitaxial layer comprising a first side and a second side, a first type contact proximate the second side of the epitaxial layer, a second type contact proximate the second side of the epitaxial layer, and a wavelength conversion element comprising at least one lumiphore. The wavelength conversion element is proximate the first side of the epitaxial layer. A distance between the at least one lumiphore of the wavelength conversion element and the epitaxial layer is less than 5 microns.

In certain embodiments, the LED chip forms a portion of a wafer comprising a plurality of integrally coupled LED chips.

In certain embodiments, the LED chip further comprises a transparent bonding layer between the wavelength conversion element and the epitaxial layer, the transparent bonding layer having a thickness less than 5 microns.

In certain embodiments, the LED chip further comprises a transparent substrate proximate the wavelength conversion element. The wavelength conversion element is positioned between the epitaxial layer and the transparent substrate.

In certain embodiments, the wavelength conversion element comprises a first planar side and a second planar side opposite to and parallel to the first planar side.

In certain embodiments, the wavelength conversion element comprises at least one of a ceramic material or phosphor in glass.

In certain embodiments, a refractive index of the wavelength conversion element is based on emission characteristics of the epitaxial layer.

In certain embodiments, the wavelength conversion element is attached to the epitaxial layer via direct or indirect wafer bonding.

In certain embodiments, the epitaxial layer and the wavelength conversion element are bounded by sidewalls.

In certain embodiments, the epitaxial layer comprises a first side and a second side, the first side of the epitaxial layer comprising texturing, the texturing having horizontally non-uniformly spaced peaks or vertically non-uniform peak heights.

In another aspect, a method comprises forming a flip-chip wafer comprising an epitaxial layer. A growth substrate is at a first side of the epitaxial layer, a first type contact is proximate a second side of the epitaxial layer, and a second type contact is proximate the second side of the epitaxial layer. The method further comprises coupling a carrier to the flip-chip wafer proximate the second side of the epitaxial layer. The method further comprises removing at least a portion of the growth substrate. The method further comprises coupling a wavelength conversion element at the first side of the epitaxial layer. The wavelength conversion element comprises at least one lumiphore. A distance between the at least one lumiphore of the wavelength conversion element and the epitaxial layer is less than 5 microns.

In certain embodiments, the method further comprises singulating a plurality of LED chips of the flip-chip wafer.

In certain embodiments, coupling the wavelength conversion element at the first side of the epitaxial layer further comprises applying a transparent bonding layer to the first side of the epitaxial layer. The transparent bonding layer has a thickness less than 5 microns. Coupling the wavelength conversion element at the first side of the epitaxial layer further comprises applying the wavelength conversion element to the transparent bonding layer.

In certain embodiments, the method further comprises applying a transparent substrate to the wavelength conversion element.

In certain embodiments, the wavelength conversion element comprises a first planar side and a second planar side opposite to and parallel to the first planar side.

In certain embodiments, the wavelength conversion element comprises at least one of a ceramic material or phosphor in glass.

In certain embodiments, the method further comprises determining a performance characteristic of the epitaxial layer and determining a desired refractive index of the wavelength conversion element based on emission characteristics of the epitaxial layer.

In certain embodiments, coupling the wavelength conversion element at the first side of the epitaxial layer further comprises coupling the wavelength conversion element to the epitaxial layer via direct or indirect wafer bonding.

In certain embodiments, the method further comprises applying sidewalls to bound the epitaxial layer and the wavelength conversion element.

In certain embodiments, the method further comprises texturing the first side of the epitaxial layer after removal of at least a portion of the growth substrate, the texturing having horizontally non-uniformly spaced peaks or vertically non-uniform peak heights.

In certain embodiments, coupling the carrier to the flip-chip wafer proximate the second side of the epitaxial layer further comprises coupling the carrier to the flip-chip wafer proximate the second side of the epitaxial layer via a temporary bond. The method further comprises removing the temporary bond to expose the first type contact and the second type contact.

In certain embodiments, coupling the carrier to the flip-chip wafer proximate the second side of the epitaxial layer further comprises coupling the carrier to the flip-chip wafer proximate the second side of the epitaxial layer via a ceramic bond. The method further comprises removing at least a portion of the ceramic bond to expose at least a portion of at least one of the first type contact or the second type contact.

In another aspect, an LED chip comprises an epitaxial layer comprising a first side and a second side. The first side of the epitaxial layer comprises texturing. The texturing has horizontally non-uniformly spaced peaks or vertically non-uniform peak heights. The LED chip further comprises a first type contact proximate the second side of the epitaxial layer, a second type contact proximate the second side of the epitaxial layer, and a wavelength conversion element comprising at least one lumiphore. The wavelength conversion element is proximate the first side of the epitaxial layer.

In certain embodiments, the LED chip forms a portion of a wafer comprising a plurality of integrally coupled LED chips.

In certain embodiments, the LED chip further comprises a transparent bonding layer between the wavelength conversion element and the epitaxial layer. The transparent bonding layer has a thickness less than 5 microns.

In certain embodiments, the LED chip further comprises a transparent substrate proximate the wavelength conversion element. The wavelength conversion element is positioned between the epitaxial layer and the transparent substrate.

In certain embodiments, the wavelength conversion element comprises a first generally planar side and a second generally planar side opposite to and parallel to the first planar side.

In certain embodiments, the wavelength conversion element comprises at least one of a ceramic material or phosphor in glass.

In certain embodiments, a refractive index of the wavelength conversion element is based on emission characteristics of the epitaxial layer.

In certain embodiments, the wavelength conversion element is attached to the epitaxial layer via direct or indirect wafer bonding.

In certain embodiments, the epitaxial layer and the wavelength conversion element are bounded by sidewalls.

In certain embodiments, a distance between the epitaxial layer and the at least one lumiphore of the wavelength conversion element is less than 5 microns.

In another aspect, a method comprises forming a flip-chip wafer comprising an epitaxial layer, a growth substrate at a first side of the epitaxial layer, a first type contact proximate a second side of the epitaxial layer, and a second type contact proximate the second side of the epitaxial layer. The method further comprises coupling a carrier to the flip-chip wafer proximate the second side of the epitaxial layer. The method further comprises removing at least a portion of the growth substrate to expose at least a portion of the epitaxial layer. The method further comprises texturing the first side of the epitaxial layer. The method further comprises coupling a wavelength conversion element at the first side of the epitaxial layer. The wavelength conversion element comprises at least one lumiphore.

In certain embodiments, the method further comprises singulating a plurality of LED chips of the flip-chip wafer.

In certain embodiments, coupling the wavelength conversion element at the first side of the epitaxial layer further comprises applying a transparent bonding layer to the first side of the epitaxial layer, the transparent bonding layer having a thickness less than 5 microns. Coupling the wavelength conversion element at the first side of the epitaxial layer further comprises applying the wavelength conversion element to the transparent bonding layer.

In certain embodiments, the method further comprises applying a transparent substrate to the wavelength conversion element.

In certain embodiments, the wavelength conversion element comprises a first generally planar side and a second generally planar side opposite to and parallel to the first planar side.

In certain embodiments, the wavelength conversion element comprises at least one of a ceramic material or phosphor in glass.

In certain embodiments, the method further comprises determining a performance characteristic of the epitaxial layer and determining a desired refractive index of the wavelength conversion element based on emission characteristics of the epitaxial layer.

In certain embodiments, coupling the wavelength conversion element at the first side of the epitaxial layer further comprises coupling the wavelength conversion element to the epitaxial layer via direct or indirect wafer bonding.

In certain embodiments, the method further comprises applying sidewalls to bound the epitaxial layer and the wavelength conversion element.

In certain embodiments, a distance between the epitaxial layer and the at least one lumiphore of the wavelength conversion element is less than 5 microns.

In certain embodiments, coupling the carrier to the flip-chip wafer proximate the second side of the epitaxial layer further comprises coupling the carrier to the flip-chip wafer proximate the second side of the epitaxial layer via a temporary bond. The method further comprises removing the temporary bond to expose the first type contact and the second type contact.

In certain embodiments, coupling the carrier to the flip-chip wafer proximate the second side of the epitaxial layer further comprises coupling the carrier to the flip-chip wafer proximate the second side of the epitaxial layer via a ceramic bond. The method further comprises removing at least a portion of the ceramic bond to expose at least a portion of at least one of the first type contact or the second type contact.

In another aspect, an LED chip comprises an epitaxial layer comprising a first side and a second side, at least one contact via proximate the first side of the epitaxial layer, and a wavelength conversion element comprising at least one lumiphore. The wavelength conversion element is proximate the first side of the epitaxial layer. The at least one contact via extends through the wavelength conversion element. The LED chip further comprises a transparent bonding layer positioned between the epitaxial layer and the wavelength conversion element. The transparent bonding layer comprises an inorganic material.

In certain embodiments, the LED chip forms a portion of a wafer comprising a plurality of integrally coupled LED chips.

In certain embodiments, the transparent bonding layer has a thickness less than 5 microns.

In certain embodiments, the wavelength conversion element comprises a first planar side and a second planar side opposite to and parallel to the first planar side.

In certain embodiments, the wavelength conversion element comprises at least one of a ceramic material or phosphor in glass.

In certain embodiments, the wavelength conversion element is devoid of organic material.

In certain embodiments, a refractive index of the wavelength conversion element is based on emission characteristics of the epitaxial layer.

In certain embodiments, the wavelength conversion element is attached to the epitaxial layer via direct or indirect wafer bonding.

In certain embodiments, the epitaxial layer and the wavelength conversion element are bounded by sidewalls.

In certain embodiments, a distance between the epitaxial layer and the at least one lumiphore of the wavelength conversion element is less than 5 microns.

In another aspect, a method comprises forming a vertical stack wafer comprising an epitaxial layer, and at least one contact via proximate a first side of the epitaxial layer. The method further comprises coupling a wavelength conversion element to the first side of the epitaxial layer by using a transparent bonding layer, the transparent bonding layer comprising an inorganic material.

In certain embodiments, the method further comprises singulating a plurality of LED chips of the vertical stack wafer.

In certain embodiments, coupling the wavelength conversion element at the first side of the epitaxial layer further comprises applying a transparent bonding layer to the first side of the epitaxial layer, the transparent bonding layer having a thickness less than 5 microns. Coupling the wavelength conversion element at the first side of the epitaxial layer further comprises applying the wavelength conversion element to the transparent bonding layer.

In certain embodiments, the wavelength conversion element comprises a first generally planar side and a second generally planar side opposite to and parallel to the first planar side.

In certain embodiments, the wavelength conversion element comprises at least one of a ceramic material or phosphor in glass.

In certain embodiments, the wavelength conversion element is devoid of organic material.

In certain embodiments, the method further comprises determining a performance characteristic of the epitaxial layer and determining a desired refractive index of the wavelength conversion element based on emission characteristics of the epitaxial layer.

In certain embodiments, coupling the wavelength conversion element at the first side of the epitaxial layer further comprises coupling the wavelength conversion element to the epitaxial layer via direct or indirect wafer bonding.

In certain embodiments, the method further comprises applying sidewalls to bound the epitaxial layer and the wavelength conversion element.

In certain embodiments, a distance between the epitaxial layer and the at least one lumiphore of the wavelength conversion element is less than 5 microns.

In another aspect, an LED chip comprises an epitaxial layer comprising a first side and a second side, a first type contact proximate the second side of the epitaxial layer, and a ceramic layer bonded to the second side of the epitaxial layer and positioned horizontally adjacent to the first type contact. The ceramic layer comprises at least 50% inorganic material.

In certain embodiments, the LED chip forms a portion of a wafer comprising a plurality of integrally coupled LED chips.

In certain embodiments, the LED chip forms a portion of a wafer comprising a plurality of LED chips integrally coupled and separated by ceramic sidewalls bounding the epitaxial layer of each of the plurality of LED chips.

In certain embodiments, the LED chip further comprises a second type contact proximate the second side of the epitaxial layer.

In certain embodiments, the LED chip further comprises a second type contact proximate the first side of the epitaxial layer.

In certain embodiments, the ceramic layer is devoid of organic material.

In certain embodiments, the ceramic layer comprises a ceramic powder with a binder.

In certain embodiments, the ceramic layer comprises at least one of sapphire, silicon dioxide, titanium dioxide, aluminum oxide, zirconium, magnesium oxide, graphite, silicon carbide, or boron nitride.

In certain embodiments, the method further comprises a ceramic sidewall bounding the epitaxial layer. The ceramic sidewall comprises at least 50% inorganic material.

In certain embodiments, the ceramic layer and the ceramic sidewall comprise at least one of a white light reflecting material, a black light absorbing material, or a phosphor light converting material.

In certain embodiments, the LED chip further comprises a wavelength conversion element comprising at least one lumiphore. The wavelength conversion element is proximate the first side of the epitaxial layer. The LED chip further comprises a transparent bonding layer between the wavelength conversion element and the epitaxial layer.

In certain embodiments, the wavelength conversion element is attached to the epitaxial layer via direct or indirect wafer bonding.

In certain embodiments, the wavelength conversion element comprises at least one of a ceramic material or phosphor in glass.

In certain embodiments, the transparent bonding layer comprises an inorganic material.

In another aspect, a method comprises forming a flip-chip wafer comprising an epitaxial layer. A growth substrate is at a first side of the epitaxial layer, a first type contact is proximate a second side of the epitaxial layer, and a second type contact is proximate the second side of the epitaxial layer. The method further comprises coupling a carrier to the flip-chip wafer proximate the second side of the epitaxial layer. The carrier comprises a ceramic layer to bond to the second side of the epitaxial layer and at least partially positioned horizontally adjacent to the first type contact. The ceramic layer comprises at least 50% inorganic material.

In certain embodiments, the method further comprises removing at least a portion of the ceramic layer to expose the first type contact and the second type contact. At least a portion of the ceramic layer remains between the first type contact and the second type contact.

In certain embodiments, the ceramic layer is devoid of organic material.

In certain embodiments, the ceramic layer comprises a ceramic powder with a binder.

In certain embodiments, the ceramic layer comprises at least one of sapphire, silicon dioxide, titanium dioxide, aluminum oxide, zirconium, magnesium oxide, graphite, silicon carbide, or boron nitride.

In certain embodiments, the method further comprises singulating a plurality of LED chips of the flip-chip wafer.

In certain embodiments, the method further comprises applying ceramic sidewall paste between each of the plurality of LED chips to form ceramic sidewalls. The ceramic sidewalls comprise at least 50% inorganic material.

In certain embodiments, the ceramic layer and the ceramic sidewalls comprise at least one of a white light reflecting material, a black light absorbing material, or a phosphor light converting material.

In another aspect, a method comprises forming a vertical stack wafer comprising an epitaxial layer, and at least one contact via proximate a first side of the epitaxial layer. The method further comprises coupling a carrier to the vertical stack wafer proximate a second side of the epitaxial layer. The carrier comprises a ceramic layer to bond to the second side of the epitaxial layer and at least partially positioned horizontally adjacent to the first type contact. The ceramic layer comprises at least 50% inorganic material.

In certain embodiments, the method further comprises removing at least a portion of the ceramic layer to expose the at least one contact via. At least a portion of the ceramic layer remains horizontally adjacent the at least one contact via.

In certain embodiments, the ceramic layer is devoid of organic material.

In certain embodiments, the ceramic layer comprises a ceramic powder with a binder.

In certain embodiments, the ceramic layer comprises at least one of sapphire, silicon dioxide, titanium dioxide, aluminum oxide, zirconium, magnesium oxide, graphite, silicon carbide, or boron nitride.

In certain embodiments, the method further comprises singulating a plurality of LED chips of the vertical stack wafer.

In certain embodiments, the method further comprises applying ceramic sidewall paste between each of the plurality of LED chips to form ceramic sidewalls. The ceramic sidewalls comprise at least 50% inorganic material.

In certain embodiments, the ceramic layer and the ceramic sidewalls comprise at least one of a white light reflecting material, a black light absorbing material, or a phosphor light converting material.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a light-emitting diode (LED) chip according to principles of the present disclosure.

FIG. 2 is cross-sectional view of an LED chip with a growth substrate removed and a wavelength conversion element attached to an epitaxial layer by a transparent bonding layer.

FIG. 3A is a cross-sectional view of the wavelength conversion element according to a first embodiment.

FIG. 3B is a cross-sectional view of the wavelength conversion element according to a second embodiment.

FIG. 4A is a cross-sectional view of an embodiment of the LED chip of FIG. 2 in a flip-chip configuration with the conversion element attached to the epitaxial layer by the transparent bonding layer.

FIG. 4B is a flowchart illustrating processing steps to manufacture the LED chip of FIG. 4A.

FIG. 5A is a cross-sectional view of an embodiment of the LED chip of FIG. 2 in a vertical stack configuration with the wavelength conversion element attached to the epitaxial layer by the transparent bonding layer.

FIG. 5B is a flowchart illustrating processing steps to manufacture the LED chip of FIG. 5A.

FIG. 6A is a cross-sectional view of an LED wafer illustrating partially forming a plurality of LED chips on a growth substrate.

FIG. 6B is a cross-sectional view of the LED wafer of FIG. 6A illustrating attaching a carrier opposite the growth substrate to the plurality of LED chips by a temporary bond.

FIG. 6C is a cross-sectional view of the LED wafer of FIG. 6A illustrating removal of the growth substrate.

FIG. 6D is a cross-sectional view of the LED wafer of FIG. 6A illustrating attaching a wavelength conversion element to the plurality of LED chips by a transparent bonding layer.

FIG. 6E is a cross-sectional view of the LED wafer of FIG. 6A illustrating removal of the carrier and the temporary bond from the plurality of LED chips.

FIG. 6F is a cross-sectional view of the LED wafer of FIG. 6A illustrating singulating the LED chips of the wafer.

FIG. 7A is a cross-sectional view of an LED wafer illustrating attaching a carrier opposite the growth substrate to the plurality of LED chips by a permanent ceramic bond.

FIG. 7B is a cross-sectional view of the LED wafer of FIG. 7A illustrating removing at least a portion of the permanent ceramic bond to expose contacts of the plurality of LED chips.

FIG. 7C is a cross-sectional view of the LED wafer of FIG. 7A illustrating singulating the LED chips of the wafer after attachment of the wavelength conversion element.

FIG. 7D is a cross-sectional view of the LED wafer of FIG. 7A illustrating applying a permanent ceramic paste between the plurality of LED chips to form sidewalls.

FIG. 7E is a cross-sectional view of an LED chip of the LED wafer of FIG. 7A illustrating re-singulating the plurality of LED chips to form a single LED chip with ceramic sidewalls.

FIG. 8A is a flowchart illustrating processing steps for forming an LED chip having a flip-chip configuration with a permanent ceramic bond.

FIG. 8B is a flowchart illustrating processing steps for forming an LED chip having a vertical stack configuration with a permanent ceramic bond.

FIG. 9A is a cross-sectional view of an LED chip illustrating a growth substrate attached to the epitaxial layer of the LED chip.

FIG. 9B is a cross-sectional view of the LED chip of FIG. 9A illustrating removal of the growth substrate from the epitaxial layer of the LED chip resulting in a patterned surface on the epitaxial layer.

FIG. 9C is a cross-sectional view of the LED chip of FIG. 9A illustrating planarizing the epitaxial layer of the LED chip to remove the patterned surface.

FIG. 9D is a cross-sectional view of the LED chip of FIG. 9A illustrating texturing the epitaxial layer of the LED chip.

FIG. 10 is a flowchart illustrating processing steps directed to texturing an LED chip.

FIG. 11A is a cross-sectional view of an LED chip illustrating removal of the growth substrate from the epitaxial layer of the LED chip resulting in a patterned surface on the epitaxial layer.

FIG. 11B is a cross-sectional view of the LED chip of FIG. 11A illustrating modifying the patterned surface of the epitaxial layer.

FIG. 12A is a cross-sectional view of an LED wafer illustrating a plurality of LED chips mounted to a carrier and a patterned surface of the epitaxial layer after removal of a growth substrate.

FIG. 12B is a cross-sectional view of the LED wafer of FIG. 12A illustrating an epitaxial bonding layer applied to the epitaxial layer and a wavelength conversion element with a wavelength conversion bonding layer, each of the epitaxial bonding layer and the wavelength conversion bonding layer being of a same type.

FIG. 12C is a cross-sectional view of the LED wafer of FIG. 12A with the wavelength conversion element attached to the plurality of LED chips by the epitaxial bonding layer and the wavelength conversion bonding layer.

FIG. 12D is a cross-sectional view of the LED wafer of FIG. 12A illustrating removal of the carrier and wavelength conversion bonding layer.

FIG. 12E is a cross-sectional view of the LED wafer of FIG. 12A illustrating singulating the plurality of LED chips.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Aspects disclosed herein relate to light-emitting diode (LED) chips and manufacturing processes thereof. In certain aspects, an LED chip includes an epitaxial layer with a first side and a second side, a first type contact proximate a second side of the epitaxial layer, and a wavelength conversion element including at least one lumiphore. In certain embodiments, in a flip-chip construction, a distance between the at least one lumiphore and the epitaxial layer is less than 5 microns and/or the first side of the epitaxial layer includes texturing. In certain embodiments, in a vertical stack construction, a transparent bonding layer between the epitaxial layer and the wavelength conversion element includes inorganic material. In certain embodiments, a ceramic layer is bonded to the second side of the epitaxial layer and positioned horizontally adjacent to the first type contact. Such configurations facilitate construction, decrease size, and/or increase performance of the LED chips.

Before delving into specific details of various aspects of the present disclosure, an overview of various elements that may be included in exemplary LED packages of the present disclosure is provided for context. An LED chip typically comprises an active LED structure or region that may have many different semiconductor layers arranged in various structures. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements may also be included in the active LED structure, including, but not limited to, buffer layers, nucleation layers, super lattice structures, un-doped layers, cladding layers, contact layers, current-spreading layers, and light extraction layers and elements. The active layer may comprise a single quantum well, a multiple quantum well, a double heterostructure, or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that may include many materials, such as sapphire, SiC, aluminum nitride (AlN), GaN, with a suitable substrate being a 4H polytype of SiC, although other SiC polytypes may also be used including 3C, 6H, and 15R polytypes. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including lower cost, having established manufacturing processes, and having good light-transmissive optical properties.

Different embodiments of the active LED structure may emit different wavelengths of light depending on the composition of the active layer and n-type and p-type layers. In certain embodiments, the active LED structure is configured to emit blue light with a peak wavelength range of approximately 430 nanometers (nm) to 480 nm. In other embodiments, the active LED structure is configured to emit green light with a peak wavelength range of 500 nm to 570 nm. In other embodiments, the active LED structure is configured to emit red light with a peak wavelength range of 600 nm to 650 nm.

In certain aspects of the present disclosure, the active LED structure may be configured to emit light that is outside the visible spectrum, including one or more portions of the UV spectrum. The UV spectrum is typically divided into three wavelength range categories denotated with letters A, B, and C. In this manner, UV-A light is typically defined as having a peak wavelength range from 315 nm to 400 nm, UV-B light is typically defined as having a peak wavelength range from 280 nm to 315 nm, and UV-C light is typically defined as having a peak wavelength range from 100 nm to 280 nm. UV LEDs are of particular interest for use in applications related to the disinfection of microorganisms in air, water, and surfaces, among others.

An LED chip may also be covered with one or more lumiphoric or other conversion materials, such as phosphors, such that at least some of the light from the LED chip is absorbed by the one or more phosphors and is converted to one or more different wavelength spectra according to the characteristic emission from the one or more phosphors. In this regard, at least one lumiphore receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2500 Kelvin (K) to 10,000K. In certain embodiments, lumiphoric materials having cyan, green, amber, yellow, orange, and/or red peak wavelengths may be used. In certain embodiments, the combination of the LED chip and the one or more phosphors emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. In certain embodiments, one or more phosphors may include yellow phosphor (e.g., YAG:Ce), green phosphor (e.g., LuAg:Ce), and red phosphor (e.g., Ca_{i-x-y}SrₓEu_{y}AlSiN₃), and combinations thereof. One or more lumiphoric materials may be provided on one or more portions of an LED chip and/or a submount in various configurations. In certain embodiments, one or more surfaces of LED chips may be conformally coated with one or more lumiphoric materials, while other surfaces of such LED chips and/or associated submounts may be devoid of lumiphoric material. In certain embodiments, a top surface of an LED chip may include lumiphoric material, while one or more side surfaces of an LED chip may be devoid of lumiphoric material. In certain embodiments, all or substantially all outer surfaces of an LED chip (e.g., other than contact-defining or mounting surfaces) are coated or otherwise covered with one or more lumiphoric materials. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied on or among one or more outer surfaces of an LED chip. In certain embodiments, one or more lumiphoric materials may be patterned on portions of one or more surfaces of an LED chip to include one or more stripes, dots, curves, or polygonal shapes. In certain embodiments, multiple lumiphoric materials may be arranged in different discrete regions or discrete layers on or over an LED chip.

Light emitted by the active layer or region of an LED chip typically has a lambertian emission pattern. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

In certain embodiments, one or more lumiphoric materials may be provided as at least a portion of a wavelength conversion element or cover structure that is provided over an LED chip. Wavelength conversion elements or cover structures may include a support element, such as a superstrate, and one or more lumiphoric materials that are provided by any suitable means, such as by coating a surface of the support element or by incorporating the lumiphoric materials within the support element. In some embodiments, the support element may be composed of a transparent material, a semi-transparent material, or a light-transmissive material, such as sapphire, SiC, silicone, and/or glass (e.g., borosilicate and/or fused quartz). Wavelength conversion elements and cover structures of the present disclosure may be formed from a bulk material which is optionally patterned and then singulated. In certain embodiments, the patterning may be performed by an etching process (e.g., wet or dry etching), or by another process that otherwise alters a surface, such as with a laser or saw. In certain embodiments, wavelength conversion elements and cover structures may be thinned before or after the patterning process is performed. In certain embodiments, wavelength conversion elements (e.g., superstrates) and cover structures may comprise a generally planar upper surface that corresponds to a light emission area of the LED package.

The term “superstrate” as used herein refers to an element placed on or over an LED chip that may include a lumiphoric material. The term “superstrate” is used herein, in part, to avoid confusion with other substrates that may be part of the semiconductor light-emitting device, such as a growth or carrier substrate of the LED chip or a submount of an LED package. The term “superstrate” is not intended to limit the orientation, location, and/or composition of the structure it describes. In some embodiments, the superstrate may be composed of a transparent material, a semi-transparent material, or a light-transmissive material, such as sapphire, SiC, silicone, and/or glass (e.g., borosilicate and/or fused quartz). Superstrates may be patterned to enhance light extraction. Superstrates may be formed from a bulk substrate which is optionally patterned and then singulated. In certain embodiments, the patterning of a superstrate may be performed by an etching process (e.g., wet or dry etching). In certain embodiments, the patterning of a superstrate may be performed by otherwise altering the surface, such as by a laser or saw. In certain embodiments, the superstrate may be thinned before or after the patterning process is performed. In certain embodiments, superstrates may comprise a generally planar upper surface that corresponds to a light emission area of the LED package. One or more lumiphoric materials may be arranged on the superstrate by, for example, spraying and/or otherwise coating the superstrate with the lumiphoric materials.

Wavelength conversion elements and cover structures may be attached to one or more LED chips using, for example, a layer of transparent adhesive. In certain embodiments, the layer of the transparent adhesive may include silicone with a refractive index in a range of about 1.3 to about 1.6 that is less than a refractive index of the LED chip on which the wavelength conversion element is placed. In various embodiments, wavelength conversion elements may comprise configurations such as phosphor in glass or ceramic phosphor plate arrangements. Phosphor in glass or ceramic phosphor plate arrangements may be formed by mixing phosphor particles with glass frit or ceramic materials, pressing the mixture into planar shapes, and firing or sintering the mixture to form a hardened structure that can be cut or separated into individual wavelength conversion elements.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In certain embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of ultraviolet (UV) LEDs, appropriate materials may be selected to provide a desired, and in certain embodiments high, reflectivity and/or a desired, and in certain embodiments low, absorption. In certain embodiments, a “light-transmissive” material may be configured to transmit at least 50% of emitted radiation of a desired wavelength.

The present disclosure may be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wirebonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction.

According to aspects of the present disclosure LED packages may include one or more elements, such as lumiphoric materials, encapsulants, light-altering materials, lenses, and electrical contacts, among others, that are provided with one or more LED chips. In certain aspects, an LED package may include a support member, such as a submount or a leadframe. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. In still further embodiments, the support structure may embody a lead frame structure. Light-altering materials may be arranged within LED packages to reflect or otherwise redirect light from the one or more LED chips in a desired emission direction or pattern.

In certain embodiments, light-altering materials are provided that may be arranged to divide different lumiphoric materials and LED chips on a common submount. The light-altering material may be adapted for dispensing or placing, and may include many different materials including light-reflective materials that reflect or redirect light, light-absorbing materials that absorb light, and materials that act as a thixotropic agent.

As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. In certain aspects, the particles may have an index or refraction that is configured to refract light emissions in a desired direction. In certain aspects, light-reflective particles may also be referred to as light-scattering particles. A weight ratio of the light-reflective particles or scattering particles to a binder may comprise a range of about 1:1 to about 2:1. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

A weight ratio of the light-absorbing material to the binder may comprise a range of about 1:400 to about 1:10. In certain embodiments, a total weight of the light-altering material includes any combination of the binder, the light-reflective material, and the light-absorbing material. In some embodiments, the binder may comprise a weight percentage that is in a range of about 10% to about 90% of the total weight of the light-altering material. The light-reflective material may comprise a weight percentage that is in a range of about 10% to about 90% of the total weight of the light-altering material. The light-absorbing material may comprise a weight percentage that is in a range of about 0% to about 15% of the total weight of the light-altering material.

In further embodiments, the binder may comprise a weight percentage that is in a range of about 25% to about 70% of the total weight of the light-altering material. The light-reflective material may comprise a weight percentage that is in a range of about 25% to about 70% of the total weight of the light-altering material. The light-absorbing material may comprise a weight percentage that is in a range of about 0% to about 5% of the total weight of the light-altering material.

In certain aspects, light-altering materials may be provided in a preformed sheet or layer that includes light-altering particles suspended in a binder. For example, light-altering particles may be suspended in a binder of silicone that is not fully cured to provide the preformed sheet of light-altering materials. A desired thickness or height of the preformed sheet may be provided by moving a doctor blade or the like across the sheet. The preformed sheet may then be positioned on and subsequently formed around an LED chip and/or a wavelength conversion element that is on the LED chip. For example, the preformed sheet may be laminated around the LED chip and/or wavelength conversion element and then the preformed sheet may be fully cured in place. One or more portions of the preformed sheet may then be removed from a primary light-emitting face of the LED chip and/or wavelength conversion element. In this manner, light-altering materials may be formed along peripheral edges or sidewalls of the LED chip and wavelength conversion element with thicknesses not previously possible with conventional dispensing techniques typically used to form light-altering materials. Additionally, light-altering materials may be provided without needing conventional submounts or lead frames as support for conventional dispensing and/or molding techniques. In this regard, LED devices with light-altering materials may be provided with reduced footprints suitable for closely-spaced LED arrangements.

Aspects of the present disclosure are provided that include optical arrangements for cover structures of LED packages for improving or otherwise tailoring emission characteristics. Such cover structures may include hard and mechanically robust structures that are positioned over one or more LED chips within an LED package. A cover structure may be configured to provide protection from environmental exposure to underlying portions of an LED package, thereby providing a more robust LED package that is well suited for applications that require high power with increased light intensity, contrast, and reliability, such as interior and exterior automotive applications. Cover structures may comprise host materials such as glass or ceramics that provide mechanically robust structures for environmental protection. Such cover structures may be fabricated by providing sheets of glass frit or ceramic precursor materials, pressing the sheets into planar shapes, and firing or sintering to form hardened structures that can be cut or separated. The resulting cover structure may be referred to as a glass plate or a ceramic plate. When lumiphoric materials, such as phosphors, are included in the glass frit or ceramic precursor materials, the resulting cover structures may be referred to as phosphor in glass plates or ceramic phosphor plates. Conventional phosphor in glass plates or ceramic phosphor plates typically have phosphor materials evenly distributed throughout the plates. While this may provide suitable brightness of LED package emissions, the conventional plates can tend to exhibit non-uniformity of emissions due to poor color over angle for light that is converted.

According to aspects of the present disclosure, cover structures with tailored optical arrangements are disclosed that may provide desired emission characteristics including brightness, uniformity, and emission patterns for associated LED packages. In certain aspects, cover structures may be fabricated by providing thin sheets of precursor materials, (e.g., glass frit, ceramic materials, binders and the like) where one or more of the thin sheets are configured with different optical arrangements from other ones of the thin sheets in order to provide different optical characteristics. The thin sheets may then be pressed and fired together to form a cover structure with a host material of glass and/or ceramic that is embedded with optical arrangements that vary in one or more of a horizontal and a vertical direction.

Optical arrangements as described herein may include one or more lateral and vertical arrangements of different regions of optical materials within the cover structure that are configured to interact with light in a different manner than the host material of the cover structure. As used herein, optical materials may include lumiphoric materials, materials with different indexes of refraction, light-scattering materials, and light-diffusing materials individually or in various combinations with one another. Various configurations of optical materials may be provided in each of the sheets before firing to provide a corresponding cover structure that provides one or more of improved light output, increased light extraction, improved emission uniformity, and improved emission contrast for the LED package.

As used herein, an antireflective layer or coating may include one or more layers that provide an index of refraction that is selected to reduce the reflection or refraction of light at an interface thereof. In certain embodiments, antireflective layers as disclosed herein may comprise single or multiple thin layers that transition from the index of refraction of one side of the interface to the other. In this regard, an antireflective layer may provide a graded index of refraction with values in a range between a first index of refraction associated with a first medium on one side of the interface and a second index of refraction associated with a second medium that is on the other side of the interface. Advantageously, by using the antireflective layer to transition between the different mediums, abrupt index of refraction changes may be avoided, which may reduce the amount of light reflected internally at the interface. Antireflective layers may include many different materials, including but not limited to one or more oxides of silicon (e.g., SiO₂), oxides of zirconium (e.g., ZrO₂), oxides of aluminum (e.g., Al₂O₃), oxides of titanium (e.g., TiO₂), oxides of indium (e.g., In₂O₃), indium tin oxide (ITO), silicon nitride (e.g., SiNₓ), magnesium fluoride (e.g., MgF₂), cerium fluoride (e.g., CeF₃), flouropolymers, and combinations thereof. Relative thicknesses of antireflective layers or sub-layers within a multi-layer antireflective structure may comprise one or more combinations of quarter-wavelength and half-wavelength values of target light, for example, the wavelength of light emitted by an LED chip and/or a wavelength of light provided by lumiphoric materials. Specific arrangements of antireflective layers or coatings in LED packages are disclosed that may provide a general reduction in the rate of total internal reflection at various interfaces, thereby improving the overall brightness of the LED packages. Such interfaces may include ones that are in a light path of a desired emission direction of the LED package as well as various interfaces that do not couple to external optics or in directions away from a desired emission direction.

As used herein, a filter layer or coating may include multiple sub-layer arrangements with variable thickness and/or index of refraction differences that collectively provide the ability to pass certain wavelengths of light while reflecting or otherwise redirecting other wavelengths of light. In various arrangements, filter layers as described herein may include one or more of a band-pass filter, a high-pass filter, a low-pass filter, and a notch or band-stop filter. A band-pass filter may be configured to promote wavelengths within a particular range to pass through while reflecting wavelengths outside of the particular range. A low-pass filter may promote wavelengths below a certain value to pass through while reflecting higher wavelengths. A high-pass filter may promote wavelengths above a certain value to pass through while reflecting lower wavelengths. Finally, a notch or band-stop filter may promote wavelengths within a particular range to be reflected while promoting wavelengths outside of the particular range to pass through. By way of non-limiting example, a band-pass filter may include alternating layers with alternating index of refraction materials (e.g., high-low) where relative layer thicknesses are chosen specifically to promote constructive interference for a specific wavelength band while reflecting wavelengths outside of the specific wavelength band. Filter layers according to the present disclosure may include any of the materials and combinations thereof as provided for the antireflective layers described above. Specific arrangements of filter layers or coatings in LED packages are disclosed that may promote reflection of unconverted light (e.g., from an LED chip) back into lumiphoric materials, thereby improving light-conversion efficiency and allowing potential reduction in thickness of the lumiphoric materials. Such reduction in thickness and corresponding amounts of lumiphoric material may further serve to reduce heat generation from the lumiphoric material during operation. In the example of a blue LED chip with a longer wavelength lumiphoric material, an exemplary filter layer may be configured to reduce the amount of unconverted blue light that is emitted, thereby increasing long term eye safety and reducing damage and/or fading of pigments in the LED package or external to the LED package.

As used herein, a reflective layer or coating may include one or more layers of dielectric and/or metal materials that are configured to primarily reflect visible wavelengths of light. For example, a reflective layer or coating may include one or more of a dielectric or oxide layer such as SiO₂, a multiple layer dielectric reflector such as a periodic or aperiodic Bragg reflector, and a reflective metal layer. In still further embodiments, a reflective layer or coating may include light-altering particles that are suspended in a binder in a similar manner as other light-altering materials described herein. In such embodiments, a loading of light-altering materials in a binder for the reflective layer may be higher, lower, or even the same as the other light-altering materials.

Light that is generated by the active region of the LED chip may be omnidirectional in nature and LED packages are typically designed with features that are arranged to redirect light from the active region toward a desired emission direction. For example, a desired emission direction for the LED package may be perpendicular with an interface between the LED chip and the submount. As light is generated omnidirectionally by the LED chip and must pass through multiple interfaces within the LED package, not all light may ultimately emit from the LED package in the desired emission direction. For example, some light may traverse laterally within the LED chip and may refract laterally within the LED package, such as at an interface between the LED chip and the lumiphoric material. In this regard, the light-altering material can be arranged around a perimeter of the LED chip on the submount to reflect or otherwise redirect light toward the desired emission direction. In various configurations, the light-altering material may comprise light-altering particles such as one or more of fused silica, fumed silica, zinc oxides, tantalum oxides, zirconium oxides, niobium oxides, yttrium oxides, alumina, glass beads, and TiO₂ that are suspended or embedded within a binder such as silicone or epoxy. In many applications, the light-altering material, including the light-altering particles are selected to reflect broad spectrum white light including photons ranging in wavelength from 400 nm to 700 nm.

In order for light to pass in a desired emission direction, light from the LED chip may traverse through the lumiphoric layer and the superstrate in order to escape the LED package, either directly or after reflections with one or more of the substrate and the light-altering material. Each of the LED chip, the lumiphoric material, the superstrate, and the external environment (e.g., air, or other fixture environments) above the superstrate may have a different index of refraction. As such, light traversing through each interface may refract along a different angle according to the principles of Snell's law.

Aspects as disclosed herein may be useful for LED modules, systems or fixtures that include closely-spaced LED emitters or devices that are capable of providing overall combined emissions as well as a number of changeable, selectable, or tunable emission characteristics that are provided by separately controlling the LED devices. In this manner, LED devices are arranged as close to one another as possible so they may appear as a single emission area when all are electrically activated, and when different emissions characteristics are desired, certain ones or groups of closely-spaced LED devices may be separately electrically activated or deactivated. In such applications, size and spacing limitations can make it impractical to use separately packaged LEDs. Conventional LED packages typically include an LED chip that is mounted on a larger submount and an encapsulant that encloses the LED chip on the submount, thereby providing the LED package with an increased footprint relative to the LED chip. Additionally, conventional LED packages may also include multiple LED chips that are arranged on a common substrate (e.g., a ceramic panel) or a leadframe package. However, this also contributes to an increased package footprint in order to accommodate the common substrate or leadframe. This increased footprint can be undesirable for manufacturers that want to build pixelated lighting systems, such as those used for adaptive automotive headlights or display applications.

LED devices may be provided with reduced footprints that allow for the assembly of arrays of closely-spaced LED devices on common supports, such as printed circuit boards (PCBs). LED devices as disclosed herein may be fabricated to be devoid of conventional submounts and leadframes that contribute to increased footprints. In certain aspects, an LED device that is capable of being attached to external electrical connections, such as those provided on a PCB, without the use of a conventional submount and leadframe may be referred to as a chip scale package (CSP). In this regard, a CSP may include one or more elements, such as lumiphoric materials, encapsulants, light-altering materials, lenses, and electrical contacts, among others, that are provided with one or more LED chips without a conventional submount or leadframe. For closely-spaced applications, the LED devices (e.g., CSPs) may also be configured to avoid interaction or cross-talk that may be caused by emissions that bleed over from adjacent LED devices. In this regard, LED devices as disclosed herein may be configured with a footprint that is close to a footprint of the LED chip within the LED device while also providing an amount of light-altering material around peripheral edges of the LED chip to reduce cross-talk.

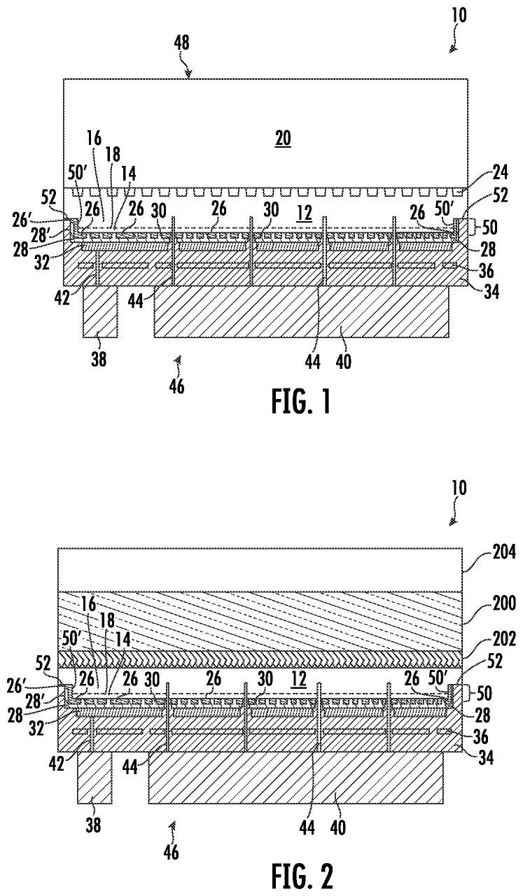

FIG. 1 is a cross-sectional view of an LED chip 10 arranged in a flip-chip configuration. While a flip-chip configuration is shown, other LED chip structures are also possible. The LED chip 10 includes an active structure 12 (may also be referred to as an epitaxial layer structure, active LED structure, etc.) comprising a p-type layer 14 (may also be referred to as a p-type sublayer), an n-type layer 16 (may also be referred to as an n-type sublayer), and an active layer 18 (may also be referred to as an active sublayer) formed on a substrate 20 (may also be referred to as a growth substrate). In certain embodiments, the n-type layer 16 is arranged between the active layer 18 and the substrate 20. In other embodiments, the doping order may be reversed such that layer 16 is doped p-type and layer 14 is doped n-type. The substrate 20 may comprise many different materials such as SiC or sapphire and may have one or more surfaces that are shaped, textured, or patterned to enhance light extraction. In certain embodiments, the substrate 20 is light transmissive (preferably transparent) and may include a patterned surface 24 that is proximate the epitaxial layer structure 12 and includes multiple recessed and/or raised features. In certain embodiments, the patterned surface 24 is adjacent the n-type layer 16 of the epitaxial layer structure 12. The patterned surface 24 is particularly useful in embodiments in which the substrate 20 comprises sapphire in order to promote extraction of light through an interface between the epitaxial layer structure 12 and the substrate 20.

In FIG. 1, a first reflective layer 26 is provided on the p-type layer 14. In certain embodiments, a current spreading layer may be provided between the p-type layer 14 and the first reflective layer 26. The current spreading layer may include a thin layer of a transparent conductive oxide such indium tin oxide (ITO) or a metal such as platinum (Pt), although other materials may be used. The first reflective layer 26 may comprise many different materials and preferably comprises a material that presents an index of refraction step with the material comprising the epitaxial layer structure 12 to promote total internal reflection (TIR) of light generated from the epitaxial layer structure 12. Light that experiences TIR is redirected without experiencing absorption or loss and may thereby contribute to useful or desired LED chip emission. In certain embodiments, the first reflective layer 26 comprises a material with an index of refraction lower than the index of refraction of the epitaxial layer structure 12 material. The first reflective layer 26 may comprise many different materials, with some having an index of refraction less than 2.3, while others may have an index of refraction less than 2.15, less than 2.0, and less than 1.5. In certain embodiments the first reflective layer 26 comprises a dielectric material, with certain embodiments comprising silicon dioxide (SiO₂) and/or silicon nitride (SiN). It is understood that many dielectric materials may be used such as SiN, SiNₓ, Si₃N₄, Si, germanium (Ge), SiO₂, SiOx, titanium dioxide (TiO₂), tantalum pentoxide (Ta₂O₅), ITO, magnesium oxide (MgOx), zinc oxide (ZnO), and combinations thereof. In certain embodiments, the first reflective layer 26 may include multiple alternating layers of different dielectric materials, e.g., alternating layers of SiO₂ and SiN that symmetrically repeat or are asymmetrically arranged. Some Group III nitride materials such as GaN may have an index of refraction of approximately 2.4, SiO₂ may have an index of refraction of approximately 1.48, and SiN may have an index of refraction of approximately 1.9. Embodiments with an epitaxial layer structure 12 comprising GaN and a first reflective layer 26 that comprises SiO₂ may have a sufficient index of refraction between the two to allow for efficient TIR of light. The first reflective layer 26 may have different thicknesses depending on the type of materials used, with certain embodiments having a thickness of at least 0.2 microns (μm). In some of these embodiments, the first reflective layer 26 may have a thickness in the range of 0.2 μm to 0.7 μm, while in some of these embodiments it may be approximately 0.5 μm thick.

In FIG. 1, the LED chip 10 may further include a second reflective layer 28 that is on the first reflective layer 26 such that the first reflective layer 26 is arranged between the epitaxial layer structure 12 and the second reflective layer 28. The second reflective layer 28 may include a metal layer that is configured to reflect any light from the epitaxial layer structure 12 that may pass through the first reflective layer 26. The second reflective layer 28 may comprise many different materials such as Ag, gold (Au), Al, or combinations thereof. As illustrated, the second reflective layer 28 may include one or more reflective layer interconnects 30 that provide an electrically conductive path through the first reflective layer 26. In certain embodiments, the reflective layer interconnects 30 comprise reflective layer vias. Accordingly, the first reflective layer 26, the second reflective layer 28, and the reflective layer interconnects 30 form a reflective structure of the LED chip 10. In certain embodiments, the reflective layer interconnects 30 comprise the same material as the second reflective layer 28 and are formed at the same time as the second reflective layer 28. In other embodiments, the reflective layer interconnects 30 may comprise a different material than the second reflective layer 28. The LED chip 10 may also comprise a barrier layer 32 on the second reflective layer 28 to prevent migration of the second reflective layer 28 material, such as Ag, to other layers. Preventing this migration helps the LED chip 10 maintain efficient operation through its lifetime. The barrier layer 32 may comprise an electrically conductive material, with suitable materials including but not limited to sputtered Ti/Pt followed by evaporated Au bulk material or sputtered Ti/Ni followed by an evaporated Ti/Au bulk material. A passivation layer 34 is included on the barrier layer 32 as well as any portions of the second reflective layer 28 that may be uncovered by the barrier layer 32. The passivation layer 34 protects and provides electrical insulation for the LED chip 10 and may comprise many different materials, such as a dielectric material. In certain embodiments, the passivation layer 34 is a single layer, and in other embodiments, the passivation layer 34 comprises a plurality of layers. A suitable material for the passivation layer 34 includes but is not limited to silicon nitride. In certain embodiments, the passivation layer 34 includes a metal-containing interlayer 36 arranged therein, wherein the interlayer 36 may comprise Al or another suitable metal. Notably, the interlayer 36 is embedded within the passivation layer 34 and is electrically isolated from the rest of the LED chip 10. In application, the interlayer 36 may function as a crack stop layer for any cracks that may propagate through the passivation layer 34. Additionally, the interlayer 36 may reflect at least some light that may pass through both the first reflective layer 26 and the second reflective layer 28.

In FIG. 1, the LED chip 10 comprises a p-contact 38 and an n-contact 40 that are arranged on the passivation layer 34 and are configured to provide electrical connections with the epitaxial layer structure 12. The p-contact 38, which may also be referred to as an anode contact, may comprise one or more p-contact interconnects 42 that extend through the passivation layer 34 to the barrier layer 32 or the second reflective layer 28 to provide an electrical path to the p-type layer 14. In certain embodiments, the one or more p-contact interconnects 42 comprise one or more p-contact vias. The n-contact 40, which may also be referred to as a cathode contact, may comprise one or more n-contact interconnects 44 that extend through the passivation layer 34, the barrier layer 32, the first and second reflective layers 26, 28, the p-type layer 14, and the active layer 18 to provide an electrical path to the n-type layer 16. In certain embodiments, the one or more n-contact interconnects 44 comprise one or more n-contact vias. In operation, a signal applied across the p-contact 38 and the n-contact 40 is conducted to the p-type layer 14 and the n-type layer 16, causing the LED chip 10 to emit light from the active layer 18. The p-contact 38 and the n-contact 40 may comprise many different materials such as Au, copper (Cu), nickel (Ni), In, Al, Ag, tin (Sn), Pt, or combinations thereof. In still other embodiments, the p-contact 38 and the n-contact 40 may comprise conducting oxides and transparent conducting oxides such as ITO, nickel oxide (NiO), ZnO, cadmium tin oxide, indium oxide, tin oxide, magnesium oxide, ZnGa₂O₄, ZnO₂/Sb, Ga₂O₃/Sn, AgInO₂/Sn, In₂O₃/Zn, CuAlO₂, LaCuOS, CuGaO₂, and SrCu₂O₂. The choice of material used may depend on the location of the contacts and on the desired electrical characteristics, such as transparency, junction resistivity, and sheet resistance. As described above, the LED chip 10 is arranged for flip-chip mounting and the p-contact 38 and n-contact 40 are configured to be mounted or bonded to a surface, such as a printed circuit board. In this regard, the LED chip 10 includes a mounting face 46 that is configured to be mounted to a surface, and a primary light-emitting face 48 that is opposite the mounting face 46. In certain embodiments, the primary light-emitting face 48 comprises the substrate 20, and light emitted from the active layer 18 primarily exits the LED chip 10 through the substrate 20. In other embodiments, the substrate 20 may be removed or replaced.

As illustrated, a portion of the epitaxial layer structure 12 extends away from the substrate 20 and forms a mesa 50 with a mesa sidewall 50′. The mesa 50 may include the p-type layer 14, the active layer 18, and a portion of the n-type layer 16. The epitaxial layer structure 12 may further include at least one recess 52 that is arranged around a periphery of the LED chip 10 such that the mesa 50 is laterally bounded by at least one recess 52. As illustrated, the at least one recess 52 may be formed by a lateral portion of the n-type layer 16 that is outside the boundary of the mesa 50. When the LED chip 10 is electrically activated, light is generated in the active layer 18 that is within the mesa 50. In this regard, the mesa sidewall 50′ forms an edge of the light-emitting portion of the LED chip 10.

Often, a wavelength conversion element is applied to a top of the growth substrate 20, which results in a distance between the epitaxial layer structure 12 and the wavelength conversion element. This changes the emission profile from a 2D emission to a 3D emission. Further, a wavelength conversion element is typically applied to a singulated LED chip 10.

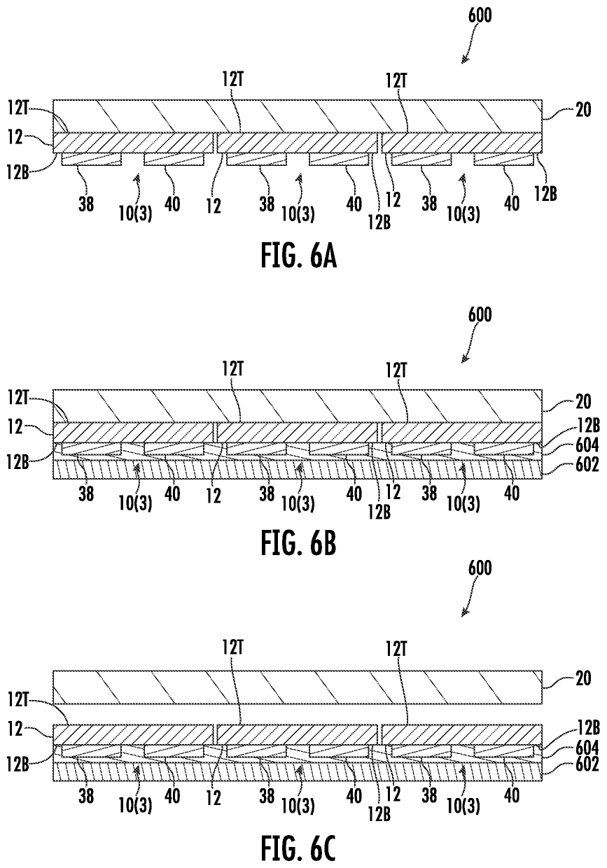

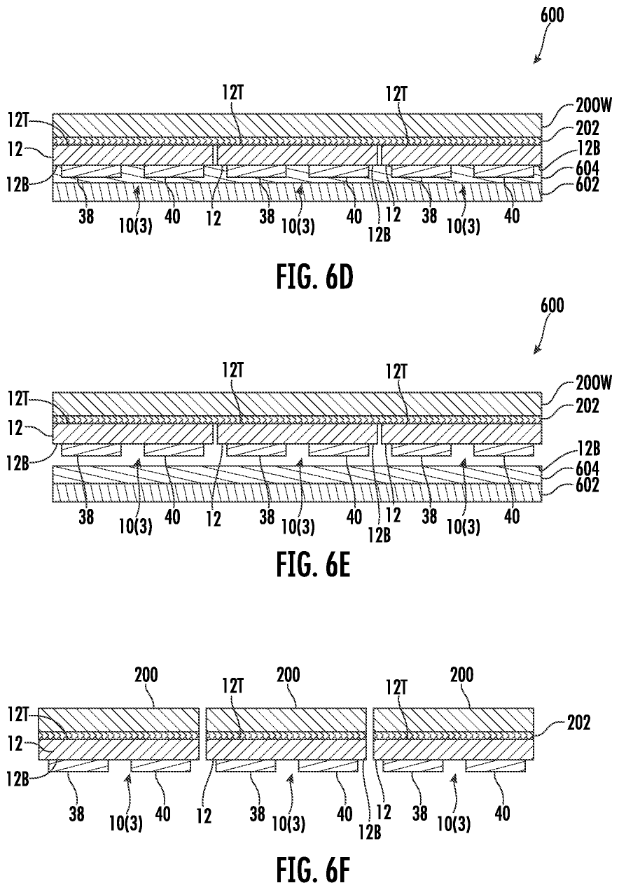

FIG. 2 is cross-sectional view of an LED chip 10 with a growth substrate 20 removed (e.g., by laser lift-off, chemical etching, mechanical removal, etc.) and a wavelength conversion element 200 attached to an epitaxial layer of an LED chip 10 by a transparent bonding layer 202. As explained in more detail below, the growth substrate 20 is removed after temporarily supporting a wafer (see, e.g., FIGS. 6A-6E, 7A-7D, 12A-12D) with a carrier (see, e.g., FIGS. 6B-6E, 7A, 12A-12C). A wavelength conversion element 200 is applied to the epitaxial layer of the LED chip 10 by a transparent bonding layer 202. This transparent bonding layer 202 is significantly thinner than the growth substrate, and accordingly, a distance between the wavelength conversion element 200 and the epitaxial layer structure 12 is significantly reduced, thereby resulting in improved operation of the LED chip 10.

In particular, such a configuration enables formation of an LED chip 10 with a wavelength conversion element 200 at the wafer level with any desired color target and spectral power distribution. Accordingly, this uses the reduced cost structure of the flip chip process to achieve the desirable emission pattern of a vertical stack configuration.

Optionally, a transparent substrate 204 may be applied to a top of the wavelength conversion element 200. In this way, the transparent substrate 204 is proximate the wavelength conversion element 200, and the wavelength conversion element 200 is positioned between the epitaxial layer structure 12 and the transparent substrate 204. Such a configuration is discussed in more detail below.

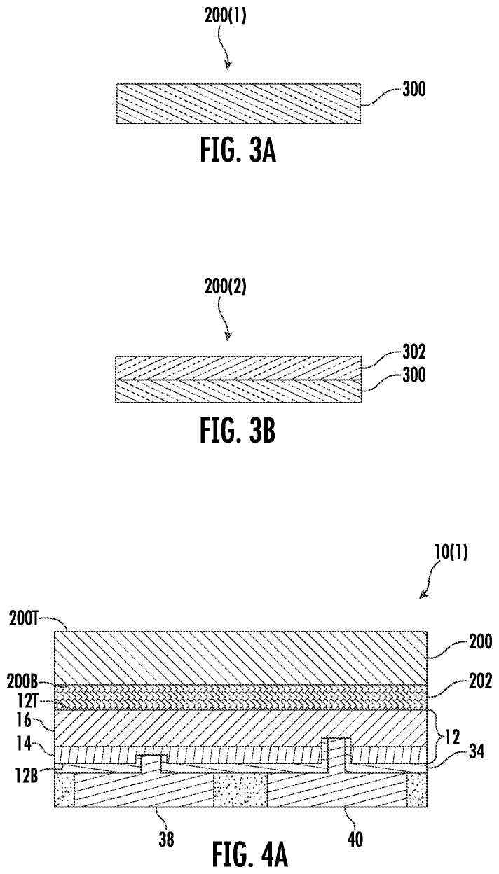

FIGS. 3A and 3B are views of embodiments of the wavelength conversion element 200. In particular, FIG. 3A is a cross-sectional view of a wavelength conversion element 200(1) according to a first embodiment. The wavelength conversion element 200(1) includes a single lumiphoric layer 300, such as including phosphor in glass and/or a ceramic phosphor plate. The lumiphoric layer 300 is self-supported. As noted above, phosphor in glass or ceramic phosphor plate arrangements may be formed by mixing phosphor particles with glass frit or ceramic materials, pressing the mixture into planar shapes, and firing or sintering the mixture to form a hardened structure that can be cut or separated into individual wavelength conversion elements. In certain embodiments, the single lumiphoric layer 300 includes a single crystal doped Ytterbium Aluminum Garnet (YAG) plate.

FIG. 3B is a cross-sectional view of a wavelength conversion element 200(2) according to a second embodiment. The wavelength conversion element 200(2) includes a lumiphoric layer 300 and a superstrate 302. In certain embodiments, the lumiphoric layer 300 includes phosphor in glass and/or a ceramic phosphor plate. In certain embodiments, the lumiphoric layer 300 includes phosphor and silicone. In certain embodiments, the superstrate 302 comprises a transparent substrate wafer, such as glass or Al₂O₃.

Accordingly, the lumiphoric layer 300 may be supported by a superstrate 302, or support element, that comprises a light-transmissive material such as glass, sapphire, or the like. The combination of the lumiphoric layer 300 and the superstrate 302, when present, comprises the wavelength conversion element 200(2). In this regard, the lumiphoric layer 300 and the superstrate 302 form a cover structure that may be arranged over the LED chip 10. The cover structure may also be referred to as a lens or even a flat lens structure, depending on its shape. The superstrate 302 of the cover structure is positioned as an exterior and light-emitting surface. In this regard, the superstrate 302 may provide protection from environmental exposure to underlying portions. In certain embodiments, the cover structure formed by the superstrate 302 and the lumiphoric layer 300 may be mounted to the LED chip 10 with a transparent adhesive material, such as silicone, and peripheral edges of the superstrate 302 and the lumiphoric layer 300 may be retained within a light-altering material.

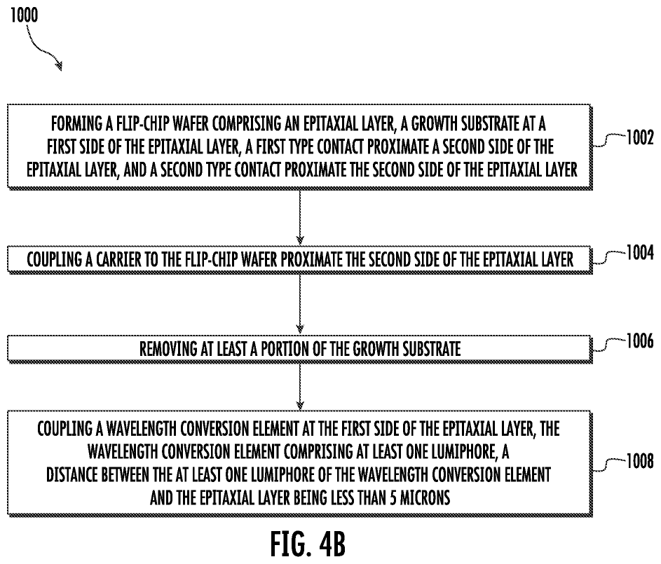

FIG. 4A is a cross-sectional view of an embodiment of the LED chip 10(1) of FIG. 2 in a flip-chip configuration with the conversion element attached to the epitaxial layer structure 12 by the transparent bonding layer 202. In particular, as similarly noted above, the LED chip 10(1) comprises a p-contact 38 (may also be referred to as a p-type contact) and an n-contact 40 (may also be referred to as an n-type contact) that are arranged on the passivation layer 34 and are configured to provide electrical connections with the epitaxial layer structure 12, including a p-type sublayer 14 and an n-type sublayer 16. The epitaxial layer structure 12 includes a top side 12T and a bottom side 12B. The p-contact 38 and the n-contact 40 are proximate the bottom side 12B of the epitaxial layer structure 12.

The LED chip 10(1) further includes the wavelength conversion element 200 including at least one lumiphore. The wavelength conversion element 200 includes at least one of a ceramic material or phosphor in glass, as similarly discussed above with respect to FIGS. 3A and 3B. In certain embodiments, the wavelength conversion element 200 includes a top planar side 200T and a bottom planar side 200B opposite to and parallel to the top planar side 200T.

A refractive index of the wavelength conversion element 200 may be based on emission characteristics of the epitaxial layer structure 12. The wavelength conversion element 200 is proximate the top side 12T of the epitaxial layer structure 12 and is attached by a transparent bonding layer 202 (e.g., via direct or indirect wafer bonding, as discussed in more detail below). The transparent bonding layer 202 may include spin-on-dielectric or spin-on-glass. For example, the transparent bonding layer 202 may include multiple spin-on-glass layers including different dopants and/or refractive indices. The transparent bonding layer 202 may include a polymer-based transparent bonding medium. In certain embodiments, the transparent bonding layer 202 is configured as a wavelength band-pass filter such that the transparent bonding layer 202 only allows certain wavelengths above and/or below a cut off value. In certain embodiments, the transparent bonding layer 202 comprises a polarizing film that only allows light with a predetermined polarization to pass through. In certain embodiments, the transparent bonding layer 202 includes a film with non-linear optical properties. In certain embodiments, the transparent bonding layer 202 is configured for scattering or focusing.

As discussed in more detail below, the wavelength conversion element 200 is applied to the epitaxial layer structure 12 after removal of the growth substrate 20 (e.g., by laser lift-off, chemical etching, mechanical removal, etc.). As noted above, the thickness of the transparent bonding layer 202 is significantly less than the thickness of the growth substrate 20, thereby reducing the distance between the wavelength conversion element 200 and the epitaxial layer structure 12. For example, in certain embodiments (e.g., a flip-chip configuration), the n-type layer 16 of the epitaxial layer structure 12 may be closer to the wavelength conversion element 200 than the p-type layer 14 of the epitaxial layer structure 12. This improves performance of the LED chip 10(1). In certain embodiments, the transparent bonding layer has a thickness less than 5 microns. In this way, a distance between the at least one lumiphore of the wavelength conversion element 200 and the epitaxial layer structure 12 is less than 5 microns. The wavelength conversion element 200 may include either wavelength conversion element 200(1), 200(2) as discussed above with respect to FIGS. 3A and 3B. If the wavelength conversion element 200(2) of FIG. 3B is used, the lumiphoric layer 300 may be positioned proximate the epitaxial layer structure 12 such that the lumiphoric layer 300 of the wavelength conversion element 200(2) is positioned between the superstrate 302 and the epitaxial layer structure 12.

As discussed in more detail below, in certain embodiments, the top side 12T of the epitaxial layer structure 12 includes texturing, where the texturing has horizontally non-uniformly spaced peaks or vertically non-uniform peak heights. Such texturing improves optical performance of the LED chip 10(1).

FIG. 4B is a flowchart 1000 illustrating processing steps to manufacture the LED chip 10(1) of FIG. 4A. The method includes forming a flip-chip wafer comprising an epitaxial layer structure 12, a growth substrate 20 at a first side 12T of the epitaxial layer structure 12, a first type contact 38 proximate a second side 12B of the epitaxial layer structure 12, and a second type contact 40 proximate the second side 12B of the epitaxial layer structure 12 (1002). The method further includes coupling a carrier to the flip-chip wafer proximate the second side 12B of the epitaxial layer structure 12 (1004). The method further includes removing at least a portion of the growth substrate 20 (1006). The method further includes coupling a wavelength conversion element 200 at the first side 12T of the epitaxial layer structure 12 (e.g., via direct or indirect wafer bonding) (1008). The wavelength conversion element 200 includes at least one lumiphore. A distance between the at least one lumiphore of the wavelength conversion element 200 and the epitaxial layer structure 12 is less than 5 microns.

In certain embodiments, coupling the wavelength conversion element 200 at the first side 12T of the epitaxial layer structure 12 includes applying a transparent bonding layer 202 to the first side 12T of the epitaxial layer structure 12. Further, coupling the wavelength conversion element 200 at the first side 12T of the epitaxial layer structure 12 includes applying the wavelength conversion element 200 to the transparent bonding layer 202.

In certain embodiments, the method further includes singulating a plurality of LED chips 10 of the flip-chip wafer. In certain embodiments, the method further includes determining a performance characteristic of the epitaxial layer structure 12 and determining a desired refractive index of the wavelength conversion element 200 based on emission characteristics of the epitaxial layer structure 12.

In certain embodiments, coupling the carrier to the flip-chip wafer proximate the second side 12B of the epitaxial layer structure 12 further includes coupling the carrier to the flip-chip wafer proximate the second side 12B of the epitaxial layer structure 12 via a temporary bond. The method further includes removing the temporary bond to expose the first type contact 38 and the second type contact 40.

In certain embodiments, coupling the carrier to the flip-chip wafer proximate the second side 12B of the epitaxial layer structure 12 further includes coupling the carrier to the flip-chip wafer proximate the second side 12B of the epitaxial layer structure 12 via a ceramic bond. The method further includes removing at least a portion of the ceramic bond to expose at least a portion of at least one of the first type contact 38 or the second type contact 40.

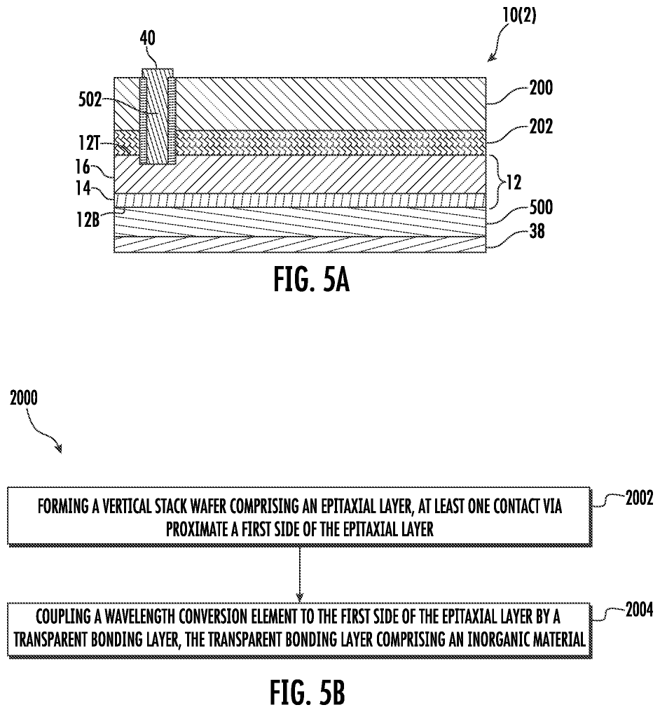

FIG. 5A is a cross-sectional view of an embodiment of the LED chip 10(2) of FIG. 2 in a vertical stack configuration with the wavelength conversion element 200 attached to the epitaxial layer structure 12 by the transparent bonding layer 202. In particular, the LED chip 10(2) includes a p-contact 38 and an n-contact 40. As similarly noted above, the epitaxial layer structure 12 includes a top side 12T and a bottom side 12B. The p-contact 38 is proximate the bottom side 12B of the epitaxial layer structure 12 and in electrical contact with the epitaxial layer structure 12 by a conductive substrate 500, such that the conductive substrate 500 is positioned between the p-contact 38 and the epitaxial layer structure 12. The n-contact 40 is proximate the top side 12T of the epitaxial layer structure 12 and in electrical contact with the epitaxial layer structure 12 through a via 502.

As similarly noted above, the LED chip 10(2) includes a wavelength conversion element 200 including at least one lumiphore. The wavelength conversion element 200 includes at least one of a ceramic material or phosphor in glass, as similarly discussed above with respect to FIGS. 3A and 3B. In certain embodiments, the wavelength conversion element 200 includes a top planar side 200T and a bottom planar side 200B opposite to and parallel to the top planar side 200T.

The wavelength conversion element 200 is proximate the top side 12T of the epitaxial layer structure 12. The n-contact 40 includes a via 502 extending through the wavelength conversion element 200 and the transparent bonding layer 202. In particular, the transparent bonding layer 202 is positioned between the epitaxial layer structure 12 and the wavelength conversion element 200. The transparent bonding layer 202 includes an inorganic material, such as ceramic. In certain embodiments, the wavelength conversion element 200 is devoid of organic material, thereby increasing reliability and durability of the LED chip 10.

A refractive index of the wavelength conversion element 200 may be based on emission characteristics of the epitaxial layer structure 12. The wavelength conversion element 200 is proximate the top side 12T of the epitaxial layer structure 12 and is attached by a transparent bonding layer 202 (e.g., via direct or indirect wafer bonding, as discussed in more detail below). As similarly noted above, the thickness of the transparent bonding layer 202 may be thin to reduce the distance between the wavelength conversion element 200 and the epitaxial layer structure 12, and accordingly improve performance of the LED chip 10(2). In certain embodiments, the transparent bonding layer has a thickness less than 5 microns. In this way, a distance between the at least one lumiphore of the wavelength conversion element 200 and the epitaxial layer structure 12 is less than 5 microns. The wavelength conversion element 200 may include either wavelength conversion element 200(1), 200(2) discussed above with respect to FIGS. 3A and 3B. If the wavelength conversion element 200(2) of FIG. 3B is used, the lumiphoric layer 300 may be positioned proximate the epitaxial layer structure 12 such that the lumiphoric layer 300 of the wavelength conversion element 200(2) is positioned between the superstrate 302 and the epitaxial layer structure 12.

As discussed in more detail below, in certain embodiments, the top side 12T of the epitaxial layer structure 12 includes texturing, where the texturing has horizontally non-uniformly spaced peaks or vertically non-uniform peak heights. Such texturing improves optical performance of the LED chip 10(2).

FIG. 5B is a flowchart 2000 illustrating processing steps to manufacture the LED chip 10(2) of FIG. 5A. The method includes forming a vertical stack wafer comprising an epitaxial layer structure 12, with at least one contact 38 via proximate a first side 12T of the epitaxial layer structure 12 (2002).

The method further includes coupling a wavelength conversion element 200 to the first side 12T of the epitaxial layer structure 12 by a transparent bonding layer 202 (e.g., via direct or indirect bonding) (2004). The transparent bonding layer 202 includes an inorganic material.

In certain embodiments, coupling the wavelength conversion element 200 at the first side 12T of the epitaxial layer structure 12 further includes applying a transparent bonding layer 202 to the first side 12T of the epitaxial layer structure 12, the transparent bonding layer 202 having a thickness less than 5 microns. Further, coupling the wavelength conversion element 200 at the first side 12T of the epitaxial layer structure 12 further includes applying the wavelength conversion element 200 to the transparent bonding layer 202.

In certain embodiments, the method further includes singulating a plurality of LED chips 10 of the vertical stack wafer. In certain embodiments, the method further includes determining a performance characteristic of the epitaxial layer structure 12 and determining a desired refractive index of the wavelength conversion element 200 based on emission characteristics of the epitaxial layer structure 12.

FIGS. 6A-6F illustrate forming LED chips 10(3) (as similarly described above with respect to FIGS. 4A-4B). In particular, FIG. 6A is a cross-sectional view of an LED wafer 600 illustrating partially forming a plurality of LED chips on a growth substrate 20. In other words, the LED chips 10(3) each form a portion of a wafer 600 including a plurality of integrally coupled LED chips 10(3). Each of the plurality of LED chips 10(3) includes an epitaxial layer structure 12 grown on the growth substrate 20 and contacts 38, 40. The growth substrate 20 may include SiC, Sapphire, SiN, AlN, GaN, etc.

FIG. 6B is a cross-sectional view of the LED wafer of FIG. 6A illustrating attaching a carrier 602 (may also be referred to as a carrier wafer) opposite the growth substrate 20 to the plurality of LED chips 10(3) by a temporary bond 604 (e.g., wax, organic polymer, etc.). The temporary bond 604 is applied at the bottom side 12B of the epitaxial layer structure 12 and covers the contacts 38, 40 of each of the LED chips 10(3). The carrier 602 may include Si, SiC, Sapphire, SiN, AlN, GaN, etc.

FIG. 6C is a cross-sectional view of the LED wafer of FIG. 6A illustrating removal of the growth substrate 20. At least a portion of the growth substrate 20 is removed from the LED chips 10(3). For example, the growth substrate 20 may be removed by laser lift-off, chemical etching, mechanical removal (e.g., grinding, polishing, etc.), etc. Accordingly, the carrier 602 (e.g., silicon) provides sufficient support and structural rigidity to support the LED chips 10(3).

FIG. 6D is a cross-sectional view of the LED wafer of FIG. 6A illustrating attaching a wavelength conversion element wafer 200W to the plurality of LED chips 10(3) by a transparent bonding layer 202. The wavelength conversion element wafer 200W provides similar support and structural rigidity as the growth substrate 20 and/or the carrier 602. As noted above, the thickness of the transparent bonding layer 202 is significantly thinner than the growth substrate 20 and decreases the distance between the wavelength conversion element wafer 200W and the epitaxial layer structure 12 for improved optical performance.

FIG. 6E is a cross-sectional view of the LED wafer of FIG. 6A illustrating removal of the carrier 602 and the temporary bond 604 from the plurality of LED chips 10(3). For example, the carrier 602 and the temporary bond 604 may be removed by heating, solvent, and/or etching, etc. As noted above, the wavelength conversion element wafer 200W provides similar support and structural rigidity as the growth substrate 20 and/or the carrier 602. As a result, the carrier 602 and/or temporary bond 604 may be removed.

FIG. 6F is a cross-sectional view of the LED wafer of FIG. 6A illustrating singulating the LED chips 10(3) of the wafer 600. As a result, each LED chip 10(3) includes a wavelength conversion element 200 supporting the epitaxial layer structure 12 and in decreased distance to the epitaxial layer structure 12.

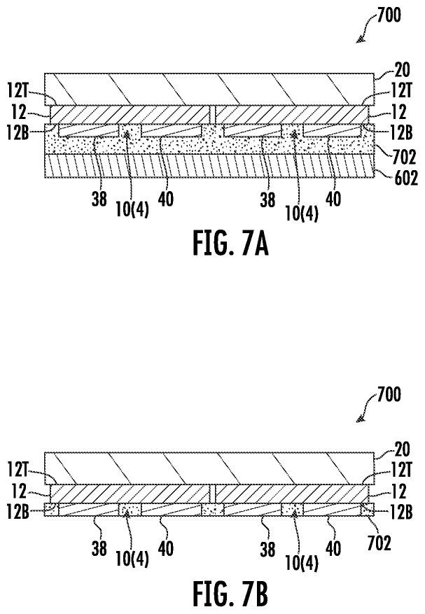

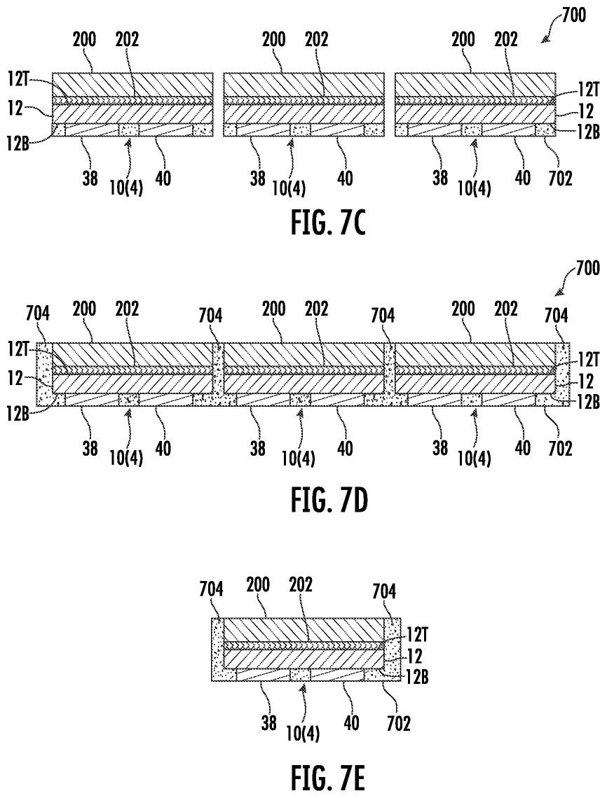

FIGS. 7A-7B illustrate LED chips with a permanent ceramic bond. In particular, FIG. 7A is a cross-sectional view of an LED wafer 700 illustrating attaching a carrier 602 opposite the growth substrate 20 to the plurality of LED chips 10(4) by a permanent ceramic bond 702. The permanent ceramic bond 702 (may also be referred to as a permanent ceramic layer, a ceramic layer, etc.) is applied at the bottom side 12B of the epitaxial layer structure 12 and covers the contacts 38, 40 of each of the LED chips 10(4). The permanent ceramic bond 702 may be applied by ceramic pastes, spin-on-dielectrics, and/or sol gel reactions (using inorganic colloidal suspension and gelation in a continuous liquid phase), etc. The material of the permanent ceramic bond 702 may be optimized based on the coefficient of thermal expansion (CTE) stress of the epitaxial layer structure 12 and/or growth substrate 20, etc. Further, the permanent ceramic bond 702 may be optimized for additional properties, such as reflection for increased light output, absorption to improve contrast in LED matrix solutions, etc. The ceramic bond 702 is incompressible and provides rigid support. Further, the ceramic bond 702 between contacts 38, 40 may be reflective (e.g., to increase brightness), and/or provide better heat conduction (e.g., than air).

FIG. 7B is a cross-sectional view of the LED wafer 700 of FIG. 7A illustrating removing at least a portion of the permanent ceramic bond 702 to expose the contacts 38, 40 of the plurality of LED chips 10(4). For example, the permanent ceramic bond 702 may be removed by grinding and/or etching. As a result, a portion of the permanent ceramic bond 702 remains between the contacts 38, 40 and surrounds each of the contacts 38, 40 of each of the plurality of LED chips 10(4). This increases the structural rigidity of the LED chips 10(4) sufficient to support the LED chips 10(4) after removal of the growth substrate 20.

FIG. 7C is a cross-sectional view of the LED wafer of FIG. 7A illustrating singulating the LED chips 10(4) of the LED wafer 700 after attachment of the wavelength conversion element 200. As similarly discussed above in FIGS. 6A-6F, after the permanent ceramic bond 702 is applied, the growth substrate 20 is removed, and the wavelength conversion element 200 and transparent bonding layer 202 are applied to the epitaxial layer structure 12. The LED chips 10(4) are then singulated.

FIG. 7D is a cross-sectional view of the LED wafer of FIG. 7A illustrating applying a permanent ceramic paste between the plurality of LED chips 10(4) to form ceramic sidewalls 704. In certain embodiments, the ceramic paste is applied between each of the singulated LED chips 10(4). As a result, the LED chips 10(4) each form a portion of the LED wafer 700 comprising a plurality of LED chips 10(4) integrally coupled and separated by ceramic sidewalls 704 bounding the epitaxial layer structure 12 of each of the plurality of LED chips 10(4).

FIG. 7E is a cross-sectional view of an LED chip of the LED wafer of FIG. 7A illustrating re-singulating the plurality of LED chips 10(4) to form a single LED chip 10(4) with ceramic sidewalls 704. In particular, after the ceramic paste is applied between the LED chips 10(4), the LED chips 10(4) are re-singulated, thereby forming ceramic sidewalls 704 that enclose the wavelength conversion element 200, the transparent bonding layer 202, and/or the epitaxial layer structure 12.

Accordingly, the LED chip 10(4) includes the contacts 38, 40 proximate the bottom side 12B of the epitaxial layer structure 12, and a ceramic layer 702 (may also be referred to as a permanent ceramic bond, ceramic bond, etc.) bonded to the bottom side 12B of the epitaxial layer structure 12 and positioned horizontally adjacent to the contacts 38, 40. The ceramic layer 702 and/or ceramic sidewalls 704 include at least 50% inorganic material (e.g., 60%, 70%, 80%, 90%, 95%, 99%, etc.). In certain embodiments, the ceramic layer 702 and/or ceramic sidewalls 704 are devoid of organic material. In certain embodiments, the ceramic layer 702 and/or ceramic sidewalls 704 comprise a ceramic powder with a binder. In certain embodiments, the ceramic layer 702 and/or ceramic sidewalls 704 include at least one of sapphire, silicon dioxide, titanium dioxide, aluminum oxide, zirconium, magnesium oxide, graphite, silicon carbide, or boron nitride.

In certain embodiments, the ceramic layer 702 and/or ceramic sidewalls 704 include at least one of a white light reflecting material, a black light absorbing material, a grey material (to balance reflection and absorption), and/or a phosphor light converting material. For example, in certain embodiments, the ceramic layer 702 and/or ceramic sidewalls 704 includes phosphor particles to control sidewall emission color, color over angle tuning, etc.

It is noted that although a flip chip configuration is illustrated, the above could also apply to a vertical stack configuration.

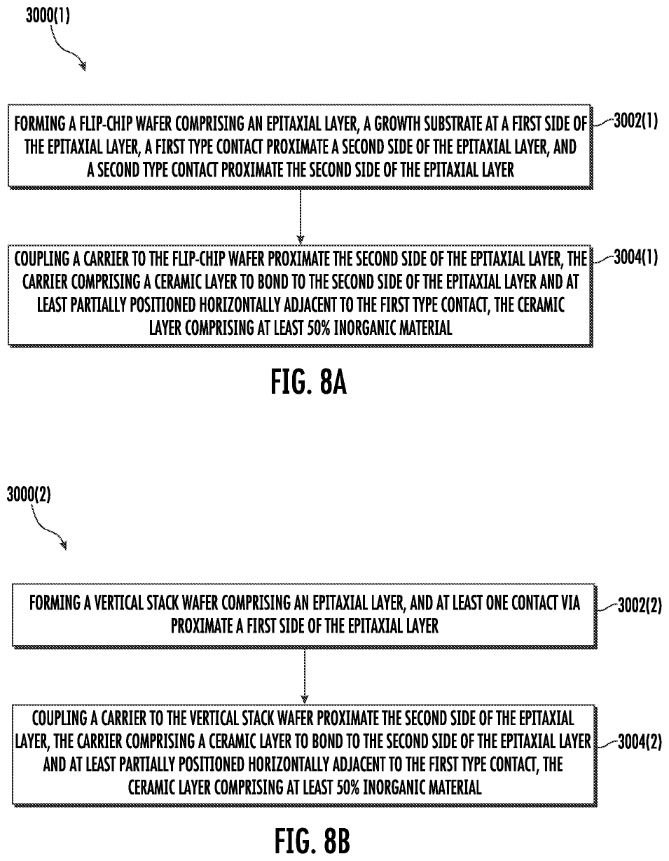

FIG. 8A is a flowchart 3000(1) illustrating processing steps for forming an LED chip 10 having a flip-chip configuration with a permanent ceramic bond. The method includes forming a flip-chip wafer comprising an epitaxial layer structure 12, a growth substrate 20 at a first side 12T of the epitaxial layer structure 12, a first type contact 38 proximate a second side 12B of the epitaxial layer structure 12, and a second type contact 40 proximate the second side 12B of the epitaxial layer structure 12 (3002(1)).

The method further includes coupling a carrier to the flip-chip wafer proximate the second side 12B of the epitaxial layer structure 12 (3004(1)). The carrier includes a ceramic layer to bond to the second side 12B of the epitaxial layer structure 12 and is at least partially positioned horizontally adjacent to the first type contact 38. The ceramic layer includes at least 50% inorganic material. In particular, the ceramic layer includes at least 50% inorganic material by mole fraction. In certain embodiments, the ceramic layer includes at least 50% inorganic material by mole fraction, weight, and/or volume, etc.

In certain embodiments, the method further includes removing at least a portion of the ceramic layer to expose the first type contact 38 and the second type contact 40. At least a portion of the ceramic layer remains between the first type contact 38 and the second type contact 40.

In certain embodiments, the method further includes singulating a plurality of LED chips 10 of the flip-chip wafer.

In certain embodiments, the method further includes applying ceramic sidewall paste between each of the plurality of LED chips 10 to form ceramic sidewalls, the ceramic sidewalls comprising at least 50% inorganic material. In particular, the ceramic layer includes at least 50% inorganic material by mole fraction. In certain embodiments, the ceramic layer includes at least 50% inorganic material by mole fraction, weight, and/or volume, etc.

FIG. 8B is a flowchart 3000(2) illustrating processing steps for forming an LED chip 10 having a vertical stack configuration with a permanent ceramic bond. The method includes forming a vertical stack wafer comprising an epitaxial layer structure 12, and at least one contact 38 via proximate a first side 12T of the epitaxial layer structure 12 (3002(2)).

The method further includes coupling a carrier to the vertical stack wafer proximate a second side 12B of the epitaxial layer (3004(2)). The carrier includes a ceramic layer to bond to the second side 12B of the epitaxial layer structure 12 and is at least partially positioned horizontally adjacent to the first type contact 38. The ceramic layer includes at least 50% inorganic material.

In certain embodiments, the method further includes removing at least a portion of the ceramic layer to expose the at least one contact 38, 40. At least a portion of the ceramic layer remains horizontally adjacent the at least one contact 38, 40.

In certain embodiments, the method further includes singulating a plurality of LED chips 10 of the vertical stack wafer.

In certain embodiments, the method further includes applying ceramic sidewall paste between each of the plurality of LED chips to form ceramic sidewalls, the ceramic sidewalls comprising at least 50% inorganic material.

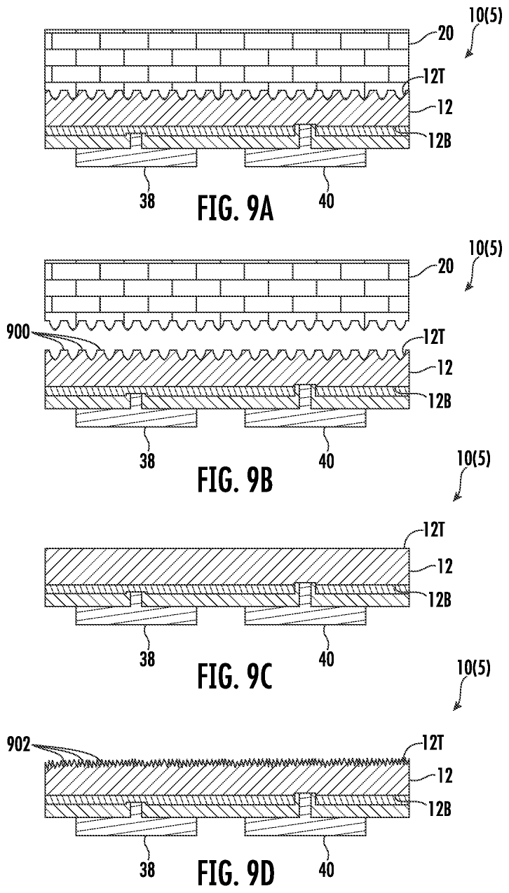

FIGS. 9A-9D illustrate texturing an LED chip 10(5). In particular, FIG. 9A is a cross-sectional view of an LED chip 10(5) illustrating a growth substrate 20 attached to the epitaxial layer structure 12 of the LED chip 10(5). In certain embodiments, the growth substrate 20 includes a patterned sapphire substrate and the epitaxial layer structure 12 includes GaN.

FIG. 9B is a cross-sectional view of the LED chip of FIG. 9A illustrating removal of the growth substrate from the epitaxial layer of the LED chip resulting in a patterned top side 12T of the epitaxial layer structure 12. In particular, when the growth substrate 20 is removed (e.g., by laser lift-off), the patterned surface of the growth substrate 20 is imprinted onto the epitaxial layer structure 12. As a result, the top side 12T is patterned as the peaks and valleys of patterned features 900 have a consistent depth and width. In other words, the height of each of the patterned features 900 is consistent across the top side 12T, and the spacing between each of the patterned features 900 is consistent across the top side 12T. The patterned surface includes frustoconical cones in a two-dimensional array, although other patterns could be made. It is noted that the growth substrate 20 may be removed by use of a carrier, as discussed above.

FIG. 9C is a cross-sectional view of the LED chip of FIG. 9A illustrating planarizing the epitaxial layer structure 12 of the LED chip 10(5) to remove the patterned features 900. FIG. 9D is a cross-sectional view of the LED chip of FIG. 9A illustrating texturing 902 (may also be referred to as textured features) on the epitaxial layer structure 12 of the LED chip 10(5). In particular, the epitaxial layer structure 12 may be textured using acid etching or the like. The textured features 902 have inconsistent height and spacing. In other words, the texturing 902 is non-uniform and non-repeating, unlike the patterned surface. The height of each of the textured features 902 is inconsistent across the top side 12T, and the spacing between each of the texturing 902 is inconsistent across the top side 12T. The texturing 902 has horizontally non-uniformly spaced peaks or vertically non-uniform peak heights.

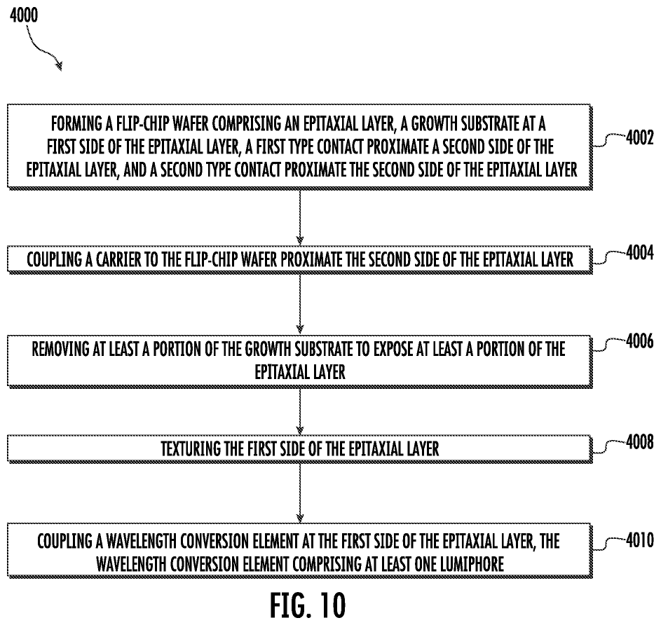

FIG. 10 is a flowchart 4000 illustrating processing steps directed to texturing an LED chip. In certain embodiments, the method includes forming a flip-chip wafer comprising an epitaxial layer structure 12, a growth substrate 20 at a first side 12T of the epitaxial layer structure 12, a first type contact 38 proximate a second side 12B of the epitaxial layer structure 12, and a second type contact 40 proximate the second side 12B of the epitaxial layer structure 12 (4002). The method further includes coupling a carrier to the flip-chip wafer proximate the second side 12B of the epitaxial layer structure 12 (4004). The method further includes removing at least a portion of the growth substrate 20 to expose at least a portion of the epitaxial layer structure 12 (4006). The method further includes texturing the first side 12T of the epitaxial layer structure 12 (4008). The method further includes coupling a wavelength conversion element 200 at the first side 12T of the epitaxial layer structure 12 (4008). The wavelength conversion element 200 includes at least one lumiphore.

In certain embodiments, the method further includes singulating a plurality of LED chips 10 of the flip-chip wafer. In certain embodiments, the method further includes applying a transparent substrate to the wavelength conversion element 200. In certain embodiments, the method further includes determining a performance characteristic of the epitaxial layer structure 12 and determining a desired refractive index of the wavelength conversion element 200 based on emission characteristics of the epitaxial layer structure 12.

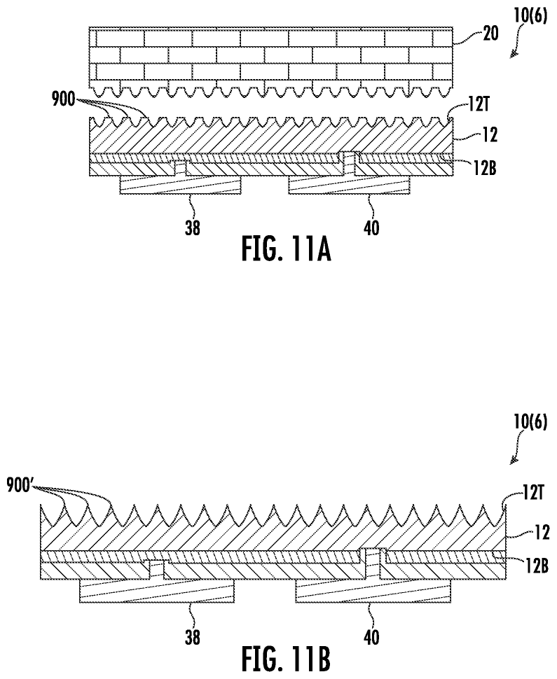

FIGS. 11A and 11B illustrate modifying a patterned surface. In particular, FIG. 11A is a cross-sectional view of an LED chip 10(6) illustrating removal of the growth substrate 20 from the epitaxial layer structure 12 of the LED chip 10(6) resulting in a patterned surface 900 (may also be referred to as patterned features) on the epitaxial layer structure 12. It is noted that the growth substrate 20 may be removed by use of a carrier, as discussed above. FIG. 11B is a cross-sectional view of the LED chip 10(6) of FIG. 11A illustrating modifying a patterned surface 900′ of the epitaxial layer structure 12, such as by acid etching. In particular, the patterned features 900 of FIG. 11A have generally blunted tips. In other words, the tip of each patterned feature 900 of FIG. 11A is wider than the tip of each modified patterned feature of FIG. 11B. The tip of each modified patterned feature 900′ is narrower.

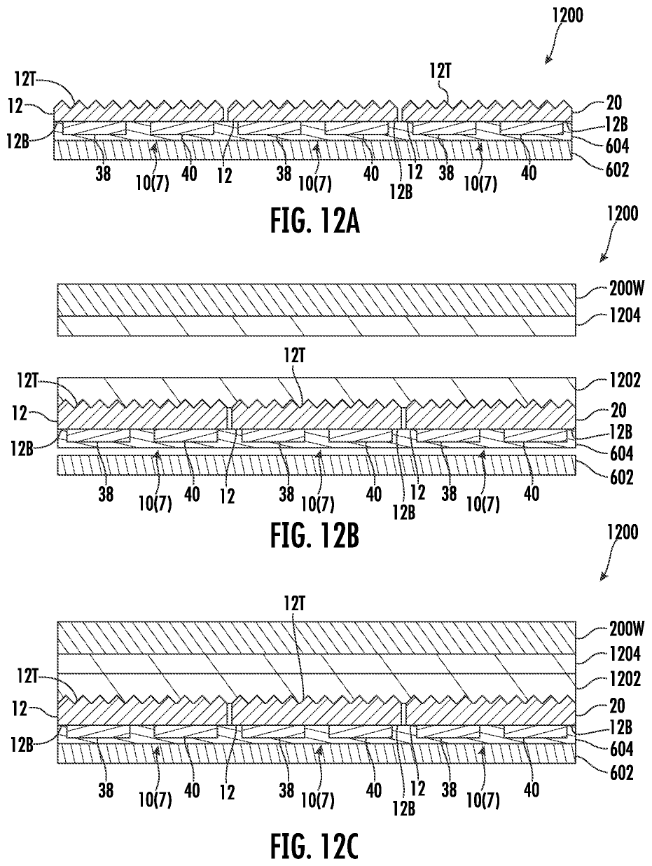

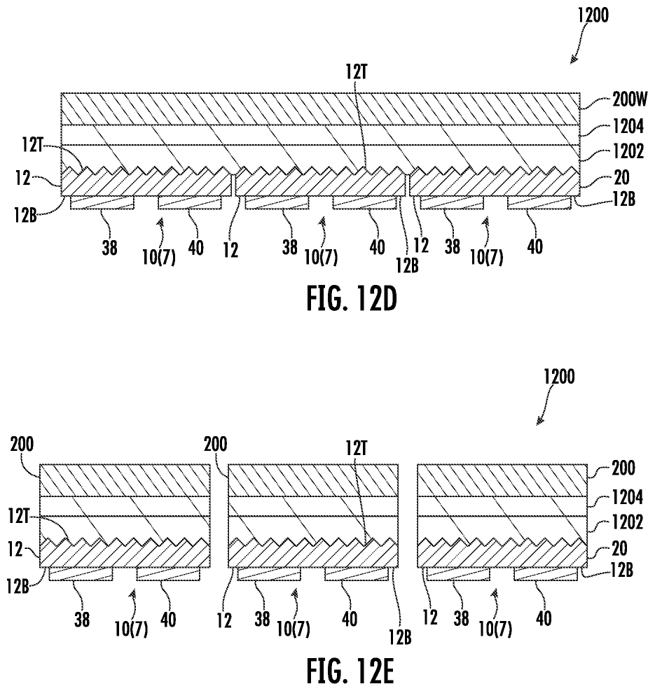

FIGS. 12A-12E illustrate direct wafer bonding. In particular, FIG. 12A is a cross-sectional view of an LED wafer 1200 illustrating a plurality of LED chips 10(7) mounted to a carrier and a patterned surface of the epitaxial layer after removal of a growth substrate. FIG. 12B is a cross-sectional view of the LED wafer of FIG. 12A illustrating an epitaxial bonding layer 1202 applied to the epitaxial layer and a wavelength conversion element wafer with a wavelength conversion bonding layer 1204, each of the epitaxial bonding layer 1202 and the wavelength conversion bonding layer 1204 being of a same type. In certain embodiments, the epitaxial bonding layer 1202 and the wavelength conversion bonding layer 1204 are of different types. For example, the epitaxial bonding layer 1202 may include SiO₂ and the wavelength conversion bonding layer 1204 may include SiN.

In certain embodiments, the epitaxial bonding layer 1202 and the wavelength conversion bonding layer 1204 include a film of SiO₂, SiN, and/or SiON, etc. In certain embodiments, the thickness of the epitaxial bonding layer 1202 and/or the wavelength conversion bonding layer 1204 is about 10 nm to 10 micrometers. The epitaxial bonding layer 1202 and the wavelength conversion bonding layer 1204 may be grown by CVD, sputtering, and/or thermally oxidized. In certain embodiments, after thin film growth, the epitaxial bonding layer 1202 and/or the wavelength conversion bonding layer 1204 undergo planarization, surface, clean, and/or surface activation.

FIG. 12C is a cross-sectional view of the LED wafer of FIG. 12A with the wavelength conversion element wafer attached to the plurality of LED chips 10(7) by the epitaxial bonding layer 1202 and the wavelength conversion bonding layer 1204. The epitaxial bonding layer 1202 and the wavelength conversion bonding layer 1204 may be bonded to each other through pressure and/or heat. As a result of direct bonding, the epitaxial bonding layer 1202 and the wavelength conversion bonding layer 1204 are covalently bonded to form a continuous, seamless interface having the same chemical composition.

FIG. 12D is a cross-sectional view of the LED wafer of FIG. 12A illustrating removal of the carrier and temporary bonding. FIG. 12E is a cross-sectional view of the LED wafer of FIG. 12A illustrating singulating the plurality of LED chips 10(7).

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light emitting diode (LED) chip, comprising:
an epitaxial layer comprising a first side and a second side;
a first type contact proximate the second side of the epitaxial layer; and
a ceramic layer bonded to the second side of the epitaxial layer and positioned horizontally adjacent to the first type contact, the ceramic layer comprising at least 50% inorganic material.

2. The LED chip of claim 1, wherein the LED chip forms a portion of a wafer comprising a plurality of integrally coupled LED chips.

3. The LED chip of claim 1, wherein the LED chip forms a portion of a wafer comprising a plurality of LED chips integrally coupled and separated by ceramic sidewalls bounding the epitaxial layer of each of the plurality of LED chips.

4. The LED chip of claim 1, further comprising a second type contact proximate the second side of the epitaxial layer.

5. The LED chip of claim 1, further comprising a second type contact proximate the first side of the epitaxial layer.

6. The LED chip of claim 1, wherein the ceramic layer is devoid of organic material.

7. The LED chip of claim 1, wherein the ceramic layer comprises a ceramic powder with a binder.

8. The LED chip of claim 1, wherein the ceramic layer comprises at least one of sapphire, silicon dioxide, titanium dioxide, aluminum oxide, zirconium, magnesium oxide, graphite, silicon carbide, or boron nitride.

9. The LED chip of claim 1, further comprising a ceramic sidewall bounding the epitaxial layer, the ceramic sidewall comprising at least 50% inorganic material.

10. The LED chip of claim 9, wherein the ceramic layer and the ceramic sidewall comprise at least one of:
a white light reflecting material;
a black light absorbing material; or
a phosphor light converting material.

11. The LED chip of claim 1, further comprising:
a wavelength conversion element comprising at least one lumiphore, the wavelength conversion element proximate the first side of the epitaxial layer; and
a transparent bonding layer between the wavelength conversion element and the epitaxial layer.

12. The LED chip of claim 11, wherein the wavelength conversion element is attached to the epitaxial layer via direct or indirect wafer bonding.

13. The LED chip of claim 11, wherein the wavelength conversion element comprises at least one of a ceramic material or phosphor in glass.

14. The LED chip of claim 11, wherein the transparent bonding layer comprises an inorganic material.

15. A method, comprising:
forming a flip-chip wafer comprising an epitaxial layer, a growth substrate at a first side of the epitaxial layer, a first type contact proximate a second side of the epitaxial layer, and a second type contact proximate the second side of the epitaxial layer; and
coupling a carrier to the flip-chip wafer proximate the second side of the epitaxial layer, the carrier comprising a ceramic layer to bond to the second side of the epitaxial layer and at least partially positioned horizontally adjacent to the first type contact, the ceramic layer comprising at least 50% inorganic material.

16. The method of claim 15, further comprising removing at least a portion of the ceramic layer to expose the first type contact and the second type contact, at least a portion of the ceramic layer remaining between the first type contact and the second type contact.

17. The method of claim 15, wherein the ceramic layer is devoid of organic material.

18. The method of claim 15, wherein the ceramic layer comprises a ceramic powder with a binder.

19. The method of claim 15, wherein the ceramic layer comprises at least one of sapphire, silicon dioxide, titanium dioxide, aluminum oxide, zirconium, magnesium oxide, graphite, silicon carbide, or boron nitride.

20. The method of claim 15, further comprising singulating a plurality of light emitting diode (LED) chips of the flip-chip wafer.

21. The method of claim 20, further comprising applying ceramic sidewall paste between each of the plurality of LED chips to form ceramic sidewalls, the ceramic sidewalls comprising at least 50% inorganic material.

22. The method of claim 21, wherein the ceramic layer and the ceramic sidewalls comprise at least one of:
a white light reflecting material;
a black light absorbing material; or
a phosphor light converting material.

23. A method, comprising:
forming a vertical stack wafer comprising an epitaxial layer, and at least one contact via proximate a first side of the epitaxial layer; and
coupling a carrier to the vertical stack wafer proximate a second side of the epitaxial layer, the carrier comprising a ceramic layer to bond to the second side of the epitaxial layer and at least partially positioned horizontally adjacent to the first type contact, the ceramic layer comprising at least 50% inorganic material.

24. The method of claim 23, further comprising removing at least a portion of the ceramic layer to expose the at least one contact via, at least a portion of the ceramic layer remaining horizontally adjacent the at least one contact via.

25. The method of claim 23, wherein the ceramic layer is devoid of organic material.

26. The method of claim 23, wherein the ceramic layer comprises a ceramic powder with a binder.

27. The method of claim 23, wherein the ceramic layer comprises at least one of sapphire, silicon dioxide, titanium dioxide, aluminum oxide, zirconium, magnesium oxide, graphite, silicon carbide, or boron nitride.

28. The method of claim 23, further comprising singulating a plurality of light emitting diode (LED) chips of the vertical stack wafer.

29. The method of claim 28, further comprising applying ceramic sidewall paste between each of the plurality of LED chips to form ceramic sidewalls, the ceramic sidewalls comprising at least 50% inorganic material.

30. The method of claim 29, wherein the ceramic layer and the ceramic sidewalls comprise at least one of:
a white light reflecting material;
a black light absorbing material; or
a phosphor light converting material.
